(19) United States
(12) Patent Application Publication
(10) Pub. No.: US 2021/0017343 A1
(43) Pub. Date: Jan. 21, 2021

(54) METHOD OF PRODUCING PURIFIED PRODUCT OF RESIN COMPOSITION FOR FORMING A PHASE-SEPARATED STRUCTURE, PURIFIED PRODUCT OF RESIN COMPOSITION FOR FORMING A PHASE-SEPARATED STRUCTURE, AND METHOD OF PRODUCING STRUCTURE CONTAINING PHASE-SEPARATED STRUCTURE

(71) Applicant: TOKYO OHKA KOGYO CO., LTD., Kawasaki-shi (JP)

(72) Inventors: Takahiro Dazai, kawasaki-shi (JP); Ken MIYAGI, kawasaki-shi (JP)

(21) Appl. No.: 16/925,995

(22) Filed: Jul. 10, 2020

(30) Foreign Application Priority Data
Jul. 16, 2019 (JP) 2019-130914
Jun. 22, 2020 (JP) 2020-107118

(51) Int. Cl. C08J 5/00

(52) U.S. Cl. CPC C08J 5/00; C08J 2353/00

(57) ABSTRACT

A method of producing a purified product of a resin composition for forming a phase-separated structure, the method including subjecting a resin composition for forming a phase-separated structure to filtration using a filter having a porous structure in which adjacent spherical cells are mutually communicating, the filter being provided with a porous membrane containing at least one resin selected from the group consisting of polyimide and polyamideimide, and the resin composition for forming a phase-separated structure including a block copolymer and an organic solvent component.

### TECHNICAL FIELD

The present invention relates to a method of producing purified product of resin composition for forming a phase-separated structure, a purified product of resin composition for forming a phase-separated structure, and a method of producing structure containing phase-separated structure.

Priority is claimed on Japanese Patent Application No. 2019-130914, filed Jul. 16, 2019, and Japanese Patent Application No. 2020-107118, filed Jun. 22, 2020, the entire contents of which are incorporated herein by reference.

### DESCRIPTION OF RELATED ART

Recently, as further miniaturization of large scale integrated circuits (LSI) proceeds, a technology for processing a more delicate structure is demanded.

In response to such demand, development has been conducted on a technology in which a fine pattern is formed using a phase-separated structure formed by self-assembly of a block copolymer having mutually incompatible blocks bonded together (see, for example, Patent Document 1).

For using a phase-separation structure of a block copolymer, it is necessary to form a self-organized nano structure by a microphase separation only in specific regions, and arrange the nano structure in a desired direction. For realizing position control and orientational control, processes such as graphoepitaxy to control phase-separated pattern by a guide pattern and chemical epitaxy to control phase-separated pattern by difference in the chemical state of the substrate are proposed (see, for example, Non-Patent Document 1).

A block copolymer forms a regular periodic structure by phase separation.

A “period of a structure” refers to a period of a phase structure observed when a phase-separated structure is formed, and is a sum of the lengths of the phases which are mutually incompatible. In the case of forming a cylinder structure which has a phase-separated structure perpendicular to a surface of a substrate, the period (L0) of the structure is the center distance (pitch) of two mutually adjacent cylinder structures.

It is known that the period (L0) of a block polymer is determined by intrinsic polymerization properties such as the polymerization degree N and the Flory-Huggins interaction parameter χ. Specifically, the repulsive interaction between different block components of the block copolymer becomes larger as the product of χ and N, “χ·N” becomes larger. Therefore, when χ·N>10 (hereafter, referred to as “strong segregation limit”), there is a strong tendency for the phase separation to occur between different blocks in the block copolymer. At the strong segregation limit, the period of the block copolymer is approximately N^{2/3}·χ^{1/6}, and a relationship represented by following formula (1) is satisfied. That is, the period of the structure is in proportion to the polymerization degree N which correlates with the molecular weight and molecular weight ratio between different blocks.

L0∝a·N^{2/3}·χ^{1/6} (1)

In the formula, L0 represents the period of the structure; a represents a parameter indicating the size of the monomer; N represents the polymerization degree; and x indicates an interaction parameter. The larger the value of the interaction parameter, the higher the phase-separation performance

Therefore, by adjusting the composition and the total molecular weight of the block copolymer, the period (L0) of the structure can be adjusted.

It is known that the periodic structure formed by a block copolymer changes to a cylinder, a lamellar or a sphere, depending on the volume ratio or the like of the polymer components. Further, it is known that the period depends on the molecular weight.

Therefore, in order to form a structure having a relatively large period (L0) using a phase-separated structure formed by self-assembly of a block copolymer, it is considered that such structure may be formed by increasing the molecular weight of the block copolymer.

### DOCUMENTS OF RELATED ART

### Patent Literature

[Patent Literature 1] Japanese Unexamined Patent Application, First Publication No. 2008-36491

### Non-Patent Documents

[Non-Patent Literature 1] Proceedings of SPIE (U.S.), vol. 7637, pp. 76370G-1 (2010)

### SUMMARY OF THE INVENTION

However, currently, in the case of forming a structure using a phase-separated structure formed by directed self-assembly of a widely used block copolymer (e.g., a block copolymer having a styrene block and a methyl methacrylate block), is was difficult to further improve the phase-separation performance

On the other hand, in a resin composition for forming a phase-separated structure containing a block polymer, it has been studied to suppress the occurrence of defects (surface defects) in order to further improve the phase-separation performance The term “defects” refers to general deficiencies within a phase-separated pattern that are detected when observed from directly above the phase-separated pattern using, for example, a surface defect detection apparatus (product name: “KLA”) manufactured by KLA-TENCOR Corporation. Examples of these deficiencies include deficiencies caused by adhesion of foreign matters and precipitates on the surface of the phase-separated pattern, such as post-developing scum (residual resin composition), foam and dust; deficiencies related to pattern shape, such as bridges formed between line patterns, and filling-up of holes of a contact hole pattern; and color irregularities of a pattern.

In addition, in materials for forming a phase-separated structure, there were problems of storage stability, namely, minute particles of foreign matters are generated while storing a resin composition solution (resin composition for forming a phase-separated structure, in the form of liquid), and the improvement thereof is desired.

The present invention takes the above circumstances into consideration, with an object of providing a method of producing purified product of resin composition for forming a phase-separated structure with reduced impurities, a purified product of resin composition for forming a phase-separated structure produced by the method, and a method of producing structure containing phase-separated structure using the purified product of resin composition for forming a phase-separated structure.

Specifically, a first aspect of the present invention is a method of producing a purified product of a resin composition for forming a phase-separated structure, the method including: subjecting a resin composition for forming a phase-separated structure to filtration using a filter having a porous structure in which adjacent spherical cells are mutually communicating, the filter being provided with a porous membrane containing at least one resin selected from the group consisting of polyimide and polyamideimide, and the resin composition for forming a phase-separated structure including a block copolymer and an organic solvent component.

A second aspect of the present invention is a method of producing a structure containing phase-separated structure, the method including: obtaining a purified product of a resin composition for forming a phase-separated structure by the method according to the first aspect; using the purified product of the resin composition to form a BCP layer containing the block copolymer on a substrate; and phase-separating the BCP layer to obtain a structure containing a phase-separated structure.

A third aspect of the present invention is a purified product of a resin composition for forming a phase-separated structure, wherein the number of objects having a size of 0.11 μm or more is less than 5/cm³, as counted by a light scattering type liquid-borne particle counter.

A fourth aspect of the present invention is a method of producing a structure containing a phase-separated structure, the method including: using the purified product of a resin composition for forming a phase-separated structure according to the third aspect to form a BCP layer containing the block copolymer on a substrate; and phase-separating the BCP layer to obtain a structure containing a phase-separated structure.

According to the present invention, there are provided a method of producing purified product of resin composition for forming a phase-separated structure with reduced impurities, a purified product of resin composition for forming a phase-separated structure produced by the method, and a method of producing structure containing phase-separated structure using the purified product of resin composition for forming a phase-separated structure.

### BRIEF DESCRIPTION OF THE DRAWINGS

FIG. 1 is a diagram schematically showing one embodiment of communicating pores which constitute a polyimide resin porous membrane.

FIG. 2 is a schematic diagram showing an example of one embodiment of the method of forming a structure containing a phase-separated structure according to the present invention.

FIG. 3 is an explanatory diagram showing an example of one embodiment of an optional step.

### DETAILED DESCRIPTION OF THE INVENTION

In the present description and claims, the term “aliphatic” is a relative concept used in relation to the term “aromatic”, and defines a group or compound that has no aromaticity.

The term “alkyl group” includes linear, branched or cyclic, monovalent saturated hydrocarbon, unless otherwise specified. The same applies for the alkyl group within an alkoxy group.

The term “alkylene group” includes linear, branched or cyclic, divalent saturated hydrocarbon, unless otherwise specified.

A “halogenated alkyl group” is a group in which part or all of the hydrogen atoms of an alkyl group is substituted with a halogen atom. Examples of the halogen atom include a fluorine atom, a chlorine atom, a bromine atom and an iodine atom.

A “fluorinated alkyl group” or a “fluorinated alkylene group” is a group in which part or all of the hydrogen atoms of an alkyl group or an alkylene group have been substituted with a fluorine atom.

The term “structural unit” refers to a monomer unit that contributes to the formation of a polymeric compound (resin, polymer, copolymer).

The case of describing “may have a substituent” includes both of the case where the hydrogen atom (—H) is substituted with a monovalent group and the case where the methylene group (—CH₂—) is substituted with a divalent group.

The term “exposure” is used as a general concept that includes irradiation with any form of radiation.

A “structural unit derived from an acrylate ester” refers to a structural unit that is formed by the cleavage of the ethylenic double bond of an acrylate ester.

An “acrylate ester” refers to a compound in which the terminal hydrogen atom of the carboxy group of acrylic acid (CH₂═CH—COOH) has been substituted with an organic group.

The acrylate ester may have the hydrogen atom bonded to the carbon atom on the α-position substituted with a substituent. The substituent (R^{α0}) that substitutes the hydrogen atom bonded to the carbon atom on the α-position is an atom other than hydrogen or a group, and examples thereof include an alkyl group of 1 to 5 carbon atoms and a halogenated alkyl group of 1 to 5 carbon atoms. Further, an acrylate ester having the hydrogen atom bonded to the carbon atom on the α-position substituted with a substituent (R^{α0}) in which the substituent has been substituted with a substituent containing an ester bond (e.g., an itaconic acid diester), or an acrylic acid having the hydrogen atom bonded to the carbon atom on the α-position substituted with a substituent (R^{α0}) in which the substituent has been substituted with a hydroxyalkylgroup or a group in which the hydroxy group within a hydroxyalkyl group has been modified (e.g., α-hydroxyalkyl acrylate ester) can be mentioned as an acrylate ester having the hydrogen atom bonded to the carbon atom on the α-position substituted with a substituent. A carbon atom on the α-position of an acrylate ester refers to the carbon atom bonded to the carbonyl group, unless specified otherwise.

Hereafter, an acrylate ester having the hydrogen atom bonded to the carbon atom on the α-position substituted with a substituent is sometimes referred to as “α-substituted acrylate ester”. Further, acrylate esters and α-substituted acrylate esters are collectively referred to as “(α-substituted) acrylate ester”.

A “structural unit derived from acrylamide” refers to a structural unit that is formed by the cleavage of the ethylenic double bond of acrylamide.

The acrylamide may have the hydrogen atom bonded to the carbon atom on the α-position substituted with a substituent, and may have either or both terminal hydrogen atoms on the amino group of acrylamide substituted with a substituent. A carbon atom on the α-position of an acrylamide refers to the carbon atom bonded to the carbonyl group, unless specified otherwise.

As the substituent which substitutes the hydrogen atom on the α-position of acrylamide, the same substituents as those described above for the substituent (Raⁱ)) on the α-position of the aforementioned α-position of the aforementioned α-substituted acrylate ester can be mentioned.

A “structural unit derived from hydroxystyrene” refers to a structural unit that is formed by the cleavage of the ethylenic double bond of hydroxystyrene. A “structural unit derived from a hydroxystyrene derivative” refers to a structural unit that is formed by the cleavage of the ethylenic double bond of a hydroxystyrene derivative.

The term “hydroxystyrene derivative” includes compounds in which the hydrogen atom at the α-position of hydroxystyrene has been substituted with another substituent such as an alkyl group or a halogenated alkyl group; and derivatives thereof. Examples of the derivatives thereof include hydroxystyrene in which the hydrogen atom of the hydroxy group has been substituted with an organic group and may have the hydrogen atom on the α-position substituted with a substituent; and hydroxystyrene which has a substituent other than a hydroxy group bonded to the benzene ring and may have the hydrogen atom on the α-position substituted with a substituent. Here, the α-position (carbon atom on the α-position) refers to the carbon atom having the benzene ring bonded thereto, unless specified otherwise.

As the substituent which substitutes the hydrogen atom on the α-position of hydroxystyrene, the same substituents as those described above for the substituent on the α-position of the aforementioned α-substituted acrylate ester can be mentioned.

A “structural unit derived from vinylbenzoic acid or a vinylbenzoic acid derivative” refers to a structural unit that is formed by the cleavage of the ethylenic double bond of vinylbenzoic acid or a vinylbenzoic acid derivative. The term “vinylbenzoic acid derivative” includes compounds in which the hydrogen atom at the α-position of vinylbenzoic acid has been substituted with another substituent such as an alkyl group or a halogenated alkyl group; and derivatives thereof. Examples of the derivatives thereof include benzoic acid in which the hydrogen atom of the carboxy group has been substituted with an organic group and may have the hydrogen atom on the α-position substituted with a substituent; and benzoic acid which has a substituent other than a hydroxy group and a carboxy group bonded to the benzene ring and may have the hydrogen atom on the α-position substituted with a substituent. Here, the α-position (carbon atom on the α-position) refers to the carbon atom having the benzene ring bonded thereto, unless specified otherwise.

The term “styrene derivative” includes compounds in which the hydrogen atom at the α-position of styrene has been substituted with another substituent such as an alkyl group or a halogenated alkyl group; and derivatives thereof. Examples of the derivatives thereof include hydroxystyrene which has a substituent other than a hydroxy group bonded to the benzene ring and may have the hydrogen atom on the α-position substituted with a substituent. Here, the α-position (carbon atom on the α-position) refers to the carbon atom having the benzene ring bonded thereto, unless specified otherwise.

A “structural unit derived from styrene” or “structural unit derived from a styrene derivative” refers to a structural unit that is formed by the cleavage of the ethylenic double bond of styrene or a styrene derivative.

As the alkyl group as a substituent on the α-position, a linear or branched alkyl group is preferable, and specific examples include alkyl groups of 1 to 5 carbon atoms, such as a methyl group, an ethyl group, a propyl group, an isopropyl group, an n-butyl group, an isobutyl group, a tert-butyl group, a pentyl group, an isopentyl group and a neopentyl group.

Specific examples of the halogenated alkyl group as the substituent on the α-position include groups in which part or all of the hydrogen atoms of the aforementioned “alkyl group as the substituent on the α-position” are substituted with halogen atoms. Examples of the halogen atom include a fluorine atom, a chlorine atom, a bromine atom and an iodine atom, and a fluorine atom is particularly desirable.

Specific examples of the hydroxyalkyl group as the substituent on the α-position include groups in which part or all of the hydrogen atoms of the aforementioned “alkyl group as the substituent on the α-position” are substituted with a hydroxy group. The number of hydroxy groups within the hydroxyalkyl group is preferably 1 to 5, and most preferably 1.

In the present invention, the “polyimide resin” means any one of polyimide and polyamideimide, or both. The polyimide and the polyamideimide may respectively have at least one functional group selected from the group consisting of a carboxy group, a salt type carboxy group, and an —NH— bond.

A porous film containing at least one of polyimide and polyamideimide may be referred to as a “polyimide resin porous film”. A porous film containing a polyimide may be referred to as a “polyimide porous film”. The porous film containing polyamideimide may be referred to as “polyamideimide porous film”.

In the present specification and claims, some structures represented by chemical formulae may have an asymmetric carbon, such that an enantiomer or a diastereomer may be present. In such a case, the one formula represents all isomers. The isomers may be used individually, or in the form of a mixture.

(Method of Producing Purified Product of Resin Composition for Forming a Phase-Separated Structure)

The method of producing purified product of resin composition for forming a phase-separated structure according to the first aspect includes a step (i) of subjecting a resin composition for forming a phase-separated structure to filtration using a filter having a porous structure in which adjacent spherical cells are mutually communicating. The filter is provided with a porous membrane containing at least one resin selected from the group consisting of polyimide and polyamideimide. The resin composition for forming a phase-separated structure includes a block copolymer and an organic solvent component.

By step (i), impurities such as particles are removed from the resin composition for forming a phase-separated structure, and a purified product of the resin composition for forming a phase-separated structure is obtained.

In the above production method, particularly by virtue of using a filter having a porous structure in which adjacent spherical cells are mutually communicating, and provided with a porous membrane containing at least one resin selected from the group consisting of polyimide and polyamideimide, high polar components and polymers which were difficult to be removed in the related art may be sufficiently removed from the resin composition for forming a phase-separated structure, and among these, high polar polymers are specifically removed.

In addition, in step (i), metal component as an impurity is sufficiently removed from the resin composition for forming a phase-separated structure. In some cases, the metal components are originally contained in the components which constitute the resin composition for forming a phase-separated structure. However, in some cases, the metal components are also incorporated from a transport path of the resin composition for forming a phase-separated structure, such as pipes or joints of production apparatuses. In step (i), for example, iron, nickel, zinc, and chromium which are easily mixed from a production apparatus or the like may be effectively removed.

<Step (i)>

Step (i) includes subjecting a resin composition for forming a phase-separated structure to filtration using a filter having a porous structure in which adjacent spherical cells are mutually communicating.

«Filter»

The filter used in this step has a porous structure in which adjacent spherical cells communicate with each other.

For example, the filtration filter may be a filter formed of a simple substance of the porous membrane in which adjacent spherical cells are mutually communicating, or may be a filter obtained by using other filtering material together with the porous membrane.

Examples of other filtering material include a nylon membrane, a polytetrafluoroethylene membrane, a tetrafluoroethylene-perfluoroalkyl vinyl ether copolymer (PFA) membrane, and membranes obtained by modifying these.

In the filtration filter, the region of the porous membrane before and after passing liquid is preferably sealed such that the feed solution of a resin composition for forming a phase-separated structure and filtrate are separated without being present in a mixed state. Examples of this method of sealing include a method of processing by adhesion of the porous membrane by photo (UV) curing, by adhesion (include adhesion by anchoring effect (heat welding or the like)) by heat, or by adhesion using an adhesive, and a method of processing by adhering the porous membrane and another filtering material by a built-in method or the like. As the filter, a filter of which the outer container formed of a thermoplastic resin (polyethylene, polypropylene, PFA, polyether sulfone (PES), polyimide, polyamideimide, or the like) is provided with the porous membrane as described above may be given.

In the filter, as the form of the porous membrane, a planar shape or a pipe shape in which the sides facing the porous membrane are matched may be given. The surface of the pipe shape porous membrane preferably is pleated from the viewpoint of the fact that the area in contact with the feed solution is increased.

Regarding “Porous Membrane in Which Adjacent Spherical Cells are Mutually Communicating”

The “porous membrane in which adjacent spherical cells are mutually communicating” which the filter is provided with has communicating pores in which adjacent spherical cells are mutually communicating. The communicating pores are communicating pores which are formed by respective pores (cells) imparting porosity to the polyimide resin porous membrane. The respective pores are preferably pores having a curved surface in the inner surface, and more preferably substantially spherical pores (spherical cells).

In the present specification, a pore in which substantially the entire inner surface of the pore is a curved surface is referred to as a “spherical cell” or a “substantially spherical pore”. The spherical cell (substantially spherical pore) forms a space in which the inner surface of the pore is substantially spherical. The spherical cell is easily formed in a case where the fine particles used in the production method of the polyimide resin porous membrane described later is substantially spherical.

The “substantially spherical” is a concept including a sphere but not necessarily limited to a sphere, and is a concept including those which are substantially spherical. The “substantially spherical” means a pore of which the sphericity defined by major diameter/minor diameter, represented by a value obtained by dividing the major diameter by the minor diameter of a particle, is within 1±0.3. The sphericity of the spherical cell is preferably within 1±0.1, more preferably 1±0.05.

In a porous membrane in which adjacent spherical cells communicate with each other, at least some of the communicating pores are formed by the adjacent spherical cells.

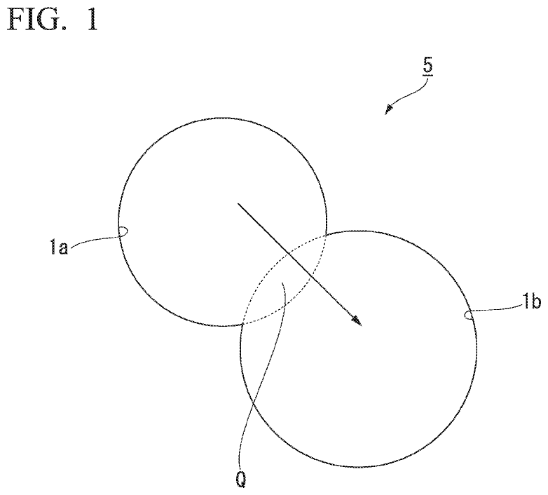

FIG. 1 schematically shows one embodiment of communicating pores which constitute a porous membrane.

In the porous membrane of the present embodiment, substantially the entire inner surface of each of a spherical cell 1a and a spherical cell 1b is a curved surface, and a substantially spherical shape space is formed.

The spherical cell 1a and the spherical cell 1b are adjacent to each other, and a communicating pores 5 through which the overlapping portion Q between the adjacent spherical cell 1a and spherical cell 1b penetrates is formed. The object of filtering, for example, flows through the inside of the communicating pore 5 in the direction (direction indicated by an arrow) of the spherical cell 1b from the spherical cell 1a.

Thus, the porous membrane having a structure in which the adjacent spherical cells are mutually communicating, it is preferable that a plurality of pores (spherical cells, communicating pores) are connected, and a flow path of an object of filtering is formed as a whole.

The “flow path” is typically formed by respective “pores” and/or “communicating pores” being mutually communicating. The respective pores, for example, are formed by the respective fine pores present in a polyimide resin-fine particle composite membrane being removed in the following step, in the production method of the polyimide resin porous membrane described below. In addition, the communicating pores are adjacent pores formed by the fine particles being removed in the following step at the portion where the respective fine pores present in a polyimide resin-fine particle composite membrane are in contact with each other, in the production method of the polyimide resin porous membrane described below.

In the porous membrane, the spherical cells and the communicating pores through which the adjacent spherical cells are mutually communicating are formed, and the extent of porosity becomes high. In addition, in the porous membrane, the spherical cells or the communicating pores are open on the porous membrane surface, the communicating pores open on the surface of one side are open on the surface of the other side (back side) by communicating the inside of the porous membrane, and a flow path through which a fluid can pass the inside of the porous membrane is formed. According to the porous membrane, by an object of filtering flowing through the flow path, foreign matters included in the object of filtering are removed from the object of filtering before filtration.

Since the porous membrane has a flow path formed of continuous communicating pores formed by the spherical cells having a curved surface in the inner surface in the inner portion, the surface area of the inner surface of the spherical cells is large. Thus, since an object of filtering is able to pass through the inner portion of the porous membrane, and when passing in contact with the curved surface of the respective the spherical cells, the contact frequency with the inner surface of the spherical cells is increased, by the foreign matters present in object of filtering being adsorbed by the inner surface of the spherical cells, the foreign matters are easily removed from the object of filtering.

The porous membrane has a structure in which the spherical cells having an average spherical diameter of from 10 to 500 nm are mutually communicating. The average diameter of the spherical cells is more preferably from 30 to 500 nm, and still more preferably from 50 to 400 nm.

The average spherical diameter of the spherical cells refers to an average value of the diameters of the communicating pores formed from two adjacent spherical cells.

The average spherical diameter of the spherical cells is a value obtained by measuring the diameter of the pore based on the bubble point method using a perm porometer (e.g., Porous Materials INC.). Specifically, the average spherical diameter can be determined by the same method as that in the average pore diameter in the porous membrane described above.

The flow path which the “porous membrane in which adjacent spherical cells are mutually communicating” has in the inner portion may have communicating pores including other shape of pores or this, in addition to the spherical cells and the communicating pores between the spherical cells.

In addition, the spherical cells may further have a recessed part on the inner surface thereof. In the recessed part, for example, pores having a pore diameter smaller than the spherical cells, open to the inner surface of the spherical cells, may be formed.

As the “porous membrane in which adjacent spherical cells are mutually communicating”, a membrane containing a resin can be given, and may be formed of substantially a resin alone, and a membrane in which the resin is preferably 95% by weight or greater, more preferably 98% by weight or greater, and still more preferably 99 by weight or greater, of the entire porous membrane may be given.

The porous membrane contains a polyimide resin. A porous film containing a polyimide resin is advantageous in terms of foreign matter removability and strength, and stability of lithographic properties before and after filtration.

The porous film contains at least one of polyimide and polyamideimide as a resin, and preferably contains at least polyimide. The porous film may contain only polyimide as a resin or may contain only polyamideimide, but a film containing only polyimide is preferable.

The “porous membrane in which adjacent spherical cells are mutually communicating” is particularly preferably at least one of polyimide and polyamideimide which is 95% by weight or greater of the entire porous membrane.

Hereinafter, a porous film (polyimide resin porous film) containing a polyimide resin as a resin and in which adjacent spherical cells communicate with each other will be described.

Polyimide Resin Porous Film

The polyimide resin may have at least one functional group selected from the group consisting of a carboxy group, a salt type carboxy group, and an —NH— bond.

The polyimide resin preferably has the functional group at a site other than the main chain terminal. As a preferable substance having the functional group at a site other than the main chain terminal, for example, polyamic acid may be given.

In the present specification, the “salt type carboxy group” means a group in which the hydrogen atom in the carboxy group has been substituted with a cationic component. The “cationic component” may be a cation itself in a completely ionized state, may be a cationic constituent element in a state where there is no charge virtually by ionic bonding with —COO⁻, or may be a cationic constituent element having a partial charge in an intermediate state of both states.

In a case where the “cationic component” is an M ion component formed of an n-valent metal M, the cation itself is represented as Mⁿ⁺, and the cationic constituent element is an element represented by “M_{1/n}” in “—COOM_{1/n}”.

As the “cationic component”, cations in a case where a compound given as a compound contained in an etching liquid described below is ion-dissociated can be given. Representatively, an ion component or an organic alkali ion component can be given. For example, in a case where an alkali metal ion component is a sodium ion component, the cation itself is a sodium ion (Na⁺), and the cationic constituent element is an element represented by “Na” in “—COONa”. The cationic constituent element having a partial charge is a Na^{δ+}.

The cationic component is not particularly limited, and inorganic components; and organic components such as NH₄⁺ and N(CH₃)₄⁺. Examples of the inorganic component include metal elements such as alkali metals including Li, Na, and K; and alkali earth metals such including Mg and Ca. Examples of the organic component include an organic alkali ion component. Examples of the organic alkali ion component include NH₄⁺, for example, quaternary ammonium cations represented by NR₄⁺ (all of four R's represent organic groups, and may be the same as or different from each other).

The organic group represented by R is preferably an alkyl group, and more preferably an alkyl group of from 1 to 6 carbon atoms. Examples of the quaternary ammonium cation include N(CH₃)₄⁺.

The state of the cationic component in a salt type carboxy group is not particularly limited, and typically, the state depends on the environment in which the polyimide resin is present, for example, environments such as an environment in which the polyimide resin is in an aqueous solution, an environment in which the polyimide resin is in an organic solvent, and an environment in which the polyimide resin is dry. In a case where the cationic component is a sodium ion component, for example, if the component is in an aqueous solution, there is a possibility that —COONa is dissociated into —COO⁻ and Na⁺, and if the component is in an organic solvent or dry, a possibility that —COONa is not dissociated is high.

The polyimide resin may have at least one functional group selected from the group consisting of a carboxy group, a salt type carboxy group, and an —NH— bond, but in the case of having at least one among these, typically, the polyimide resin has both a carboxy group and/or a salt type carboxy group and an —NH— bond. The polyimide resin may have only a carboxy group, may have only a salt type carboxy group, or may have both a carboxy group and a salt type carboxy group, in terms of a carboxy group and/or a salt type carboxy group. The ratio between the carboxy group and the salt type carboxy group of the polyimide resin can be varied depending on, for example, the environment in which the polyimide resin is present, and is affected by the concentration of the cationic component, even in the case of the same polyimide resin.

The total number of moles of the carboxy group and the salt type carboxy group of the polyimide resin is typically the same number of moles as that of the —NH— bond in the case of polyimide.

In particular, in the production method of a polyimide porous membrane described below, in a case where a carboxy group and/or a salt type carboxy group is formed from some imide bonds in the polyimide, an —NH— bond is formed substantially at the same time. The total number of moles of the carboxy group and the salt type carboxy group to be formed is equimolar to the —NH— bond to be formed.

In the case of the production method of the polyamideimide porous membrane, the total number of moles of the carboxy group and the salt type carboxy group in polyamideimide is not necessarily equimolar to an —NH— bond, and depends on the conditions of chemical etching in the etching (ring-opening of an imide bond) step described below.

The polyimide resin preferably has at least one structural unit selected from the group consisting of structural units represented by each of the following General Formulas (1) to (4).

In the case of polyimide, the polyimide preferably has at least one structural unit selected from the group consisting of a structural unit represented by the following General Formula (1) and a structural unit represented by the following General Formula (2).

In the case of polyamideimide, the polyamideimide preferably has at least one structural unit selected from the group consisting of a structural unit represented by the following General Formula (3) and a structural unit represented by the following General Formula (4).

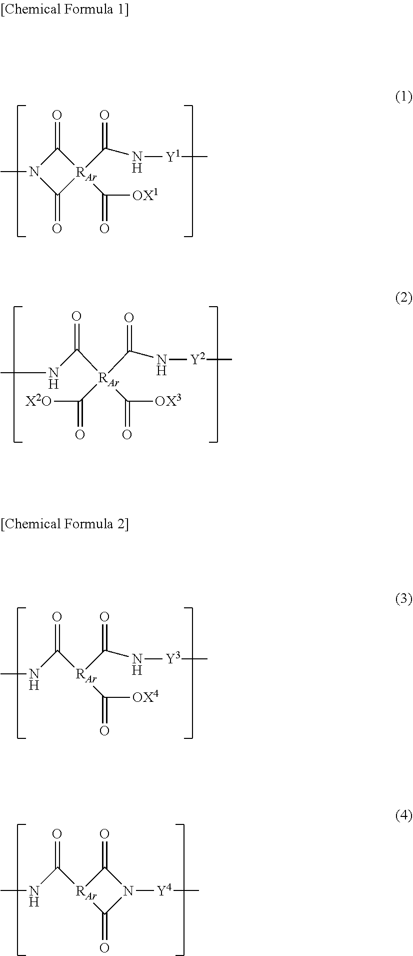

In the above formulae (1) to (3), X¹ to X⁴ may be the same as or different from each other, and are hydrogen atoms or cationic components.

R_{Ar} is an aryl group, and examples thereof include the same as aryl groups represented by R_{Ar} to which each carbonyl group is bonded in the structural unit represented by Formula (5) constituting polyamic acid described below or the structural unit represented by Formula (6) constituting aromatic polyimide.

Y¹ to Y⁴ each independently represent a divalent residue obtained by removing the amino groups of the diamine compound, and examples thereof include the same as arylene groups represented by R′ Ar to which each N is bonded in the structural unit represented by Formula (5) constituting polyamic acid described below or the structural unit represented by Formula (6) constituting aromatic polyimide.

The polyimide resin in the present invention may be a resin formed by having the structural unit represented by General Formula (1) or General Formula (2) in the case of polyimide and the structural unit represented by General Formula (3) in the case of polyamideimide by ring-opening of some of imide bonds (—N[—C(═O)]₂) of general polyimide or polyamideimide.

The polyimide resin porous membrane may contain a polyimide resin having at least one functional group selected from the group consisting of a carboxy group, a salt type carboxy group, and a —NH— bond by ring-opening some of imide bonds.

The unchanged ratio in the case of ring-opening some of imide bonds is determined by the following procedures (1) to (3).

Procedure (1): for a polyimide resin porous membrane (here, in a case where the varnish for producing the porous membrane includes polyamic acid, in the step of baking the unbaked composite membrane, it is assumed that the imidization reaction is substantially completed) on which an etching (ring-opening of an imide bond) step described below has not been performed, a value (X01) represented by the value obtained by dividing the area of the peak indicating an imide bond measured by a Fourier transform infrared spectroscopy (FT-IR) apparatus by the area of the peak indicating benzene measured by the same FT-IR apparatus is determined.

Procedure (2): with respect to the polyimide resin porous membrane obtained by using the same polymer (varnish) as the porous membrane from which the value (X01) has been determined, for the polyimide resin porous membrane after performing the etching (ring-opening of an imide bond) step described below, a value (X02) represented by the value obtained by dividing the area of the peak indicating an imide bond measured by a Fourier transform infrared spectroscopy (FT-IR) apparatus by the area of the peak indicating benzene measured by the same FT-IR apparatus is determined.

Procedure (3): the unchanged ratio is calculated by the following equation.

Unchanged ratio (%)=(X02)÷(X01)×100

The unchanged ratio of the polyimide resin porous membrane is preferably 60% or greater, more preferably from 70% to 99.5%, and still more preferably from 80% to 99%. In the case of a porous membrane containing polyamideimide, an —NH— bond is included, and thus, the unchanged ratio may be 100%.

In the case of a polyimide porous membrane, the value obtained by dividing the area of the peak indicating an imide bond measured by an FT-IR apparatus by the area of the peak indicating benzene measured by the same FT-IR apparatus is taken as “imidization ratio”.

The imidization ratio for the value (X02) determined in the procedure (2) is preferably 1.2 or greater, more preferably from 1.2 to 2, still more preferably from 1.3 to 1.6, particularly preferably from 1.30 to 1.55, and most preferably 1.35 or greater and less than 1.5. In addition, the imidization ratio for the value (X01) determined in the procedure (1) is preferably 1.5 or greater.

As the relative number of the imidization ratio is greater, the number of imide bonds is increased, that is, this indicates that the ring-opened imide bonds described above are small.

Production Method of Polyimide Resin Porous Membrane

The polyimide resin porous membrane can be produced from some of the imide bonds in the polyimide and/or the polyamideimide by a method including a step of forming a carboxy group and/or a salt type carboxy group (hereinafter, referred to as “etching step”).

In the etching step, in a case where a carboxy group and/or a salt type carboxy group is formed from some of imide bonds, substantially at the same time, an —NH— bond equimolar to these groups theoretically is also formed.

In a case where a resin containing a polyimide resin porous membrane is formed from substantially polyamideimide, the porous membrane already has an —NH— bond even without performing the etching step, and shows good adsorption ability with respect to foreign matters in an object of filtering. In this case, from the viewpoint of the fact that there is no particular need to make the flow rate of the object of filtering slow, the etching step is not necessarily required, but from the viewpoint of more effectively achieving the object of the present invention, the etching step is preferably provided.

In the production method of the polyimide resin porous membrane, the etching step is preferably performed after a resin molded membrane (hereinafter, referred to as “polyimide resin molded membrane”) having polyimide and/or polyamideimide as main components.

The polyimide resin molded membrane which is an object of the etching step may be porous or nonporous.

In addition, the form of the polyimide resin molded membrane is not particularly limited, and from the viewpoint of being capable of increasing the degree of porosity in the obtained polyimide resin porous membrane, the form is preferably a thin shape such as a membrane, and more preferably a porous shape and a thin shape such as a membrane.

As described above, the polyimide resin molded membrane may be nonporous when performing an etching step, and in this case, porosifying is preferably performed after the etching step.

As the method of porosifying a polyimide resin molded membrane before or after the etching step, a method of including the [Removal of fine particles] step of porosifying by removing the fine particles from the composite membrane of polyimide and/or polyamideimide, and fine particles (hereinafter, referred to as a “polyimide resin-fine particle composite membrane”) is preferable.

Examples of the production method of a polyimide resin porous membrane include the following production method (a) or (b).

Production method (a): a method of performing an etching step on the composite membrane of polyimide and/or polyamideimide, and fine particles, before the [Removal of fine particles] step.

Production method (b): a method of performing the etching step on the polyimide resin molded membrane porosified by the etching step after the [Removal of fine particles] step.

Among these, from the viewpoint of being capable of increasing the degree of porosity in the obtained polyimide resin porous membrane, the production method (b) is preferable.

An example of the production method of a polyimide resin porous membrane will be described below.

[Preparation of Varnish]

By mixing a fine particle dispersion obtained by dispersing fine particle in an organic solvent in advance and polyamic acid, polyimide, or polyamideimide in an arbitrary ratio, by obtaining polyamic acid by polymerizing tetracarboxylic dianhydride and diamine in the fine particle dispersion, or by obtaining polyimide by further imidizing the polyamic acid, a varnish is prepared.

The viscosity of the varnish is preferably from 300 to 2000 cP (from 0.3 to 2 Pa·s), and more preferably from 400 to 1800 cP (from 0.4 to 1.8 Pa·s). If the viscosity of the varnish is within the above range, it is possible to more uniformly form a film.

The viscosity of the varnish can be measured under a temperature condition of 25° C. using an E type rotational viscometer.

When a polyimide resin-fine particle composite membrane is obtained by baking (drying in a case where the components are arbitrary), the resin fine particles and polyamic acid, polyimide, or polyamideimide are mixed in the above-described varnish such that the ratio of the fine particles/polyimide resin preferably becomes from 1 to 4 (weight ratio), and more preferably becomes from 1.1 to 3.5 (weight ratio).

In addition, when a polyimide resin-fine particle composite membrane is obtained, the fine particles and polyamic acid, polyimide, or polyamideimide are mixed in the above-described varnish such that the volume ratio of the fine particles/polyimide resin preferably becomes from 1.1 to 5, and more preferably becomes from 1.1 to 4.5. If the weight ratio or the volume ratio is a preferable lower limit value or greater within the above range, it is possible to easily obtain pores having a proper density as a porous membrane, and if the weight ratio or the volume ratio is a preferable upper limit value or less within the above range, problems such as increase in viscosity and cracks hardly occur, and thus, it is possible to form a film.

In the present specification, the volume ratio indicates a value at 25° C.

Fine Particles

The material of the fine particles can be used without particular limitation as long as the material is insoluble in organic solvents used for varnishes, and can be selectively removed after film formation.

Examples of the inorganic material of the fine particles include metal oxides such as silica (silicon dioxide), titanium oxide, alumina (Al₂O₃), and calcium carbonate.

Examples of the organic material include organic polymers such as high molecular weight olefins (polypropylene, polyethylene, and the like), polystyrene, acrylic resins (methyl methacrylate, isobutyl methacrylate, polymethyl methacrylate (PMMA), and the like), epoxy resins, cellulose, polyvinyl alcohol, polyvinyl butyral, polyesters, polyethers, and polyethylene.

Among these, from the viewpoint of the fact that fine pores having a curved surface in the inner surface of a porous membrane are easily formed, as the inorganic material, silica such as colloidal silica is preferable. As the organic material, acrylic resins such as PMMA are preferable.

The resin fine particles, for example, can be selected from typical linear polymers or known depolymerizable polymers without particular limitation according to the purpose. The typical linear polymer is a polymer of which the molecular chain is randomly cleaved at the time of thermal decomposition. The depolymerizable polymer is a polymer which is decomposed into monomers at the time of thermal decomposition.

Since any of the polymers is also decomposed into monomers, low molecular weight substances, or CO₂ at the time of heating, the polymers can be removed from the polyimide resin membrane.

Among the depolymerizable polymers, any one of methyl methacrylate and isobutyl methacrylate (polymethyl methacrylate or poly isobutyl methacrylate) having a low thermal decomposition temperature or a copolymerization polymer which has polymethyl methacrylate or poly isobutyl methacrylate as a main component is preferable from the viewpoint of ease of handling at the time of pore formation.

The decomposition temperature of the resin fine particles is preferably from 200 to 320° C., and more preferably from 230 to 260□C. If the decomposition temperature is 200° C. or higher, it is possible to from a film even in a case where a high boiling point solvent is used in the varnish, and the range of choice in the baking conditions of the polyimide resin becomes wider. If the decomposition temperature is 320° C. or lower, it is possible to easily eliminate only the resin fine particles without causing thermal damage to the polyimide resin.

The fine particles preferably have a high sphericity from the viewpoint of the fact that the inner surface of the pores in the porous membrane to be formed is likely to have a curved surface. The particle diameter (average diameter) of the fine particles used, for example, is preferably from 50 to 2000 nm, and more preferably from 200 to 1000 nm.

If the average diameter of the fine particles is within the above range, when passing an object of filtering through the polyimide resin porous membrane obtained by removing the fine particles, it is possible to evenly bring the object of filtering into contact with the inner surface of a pore in the porous membrane, and it is possible to efficiently perform adsorption of foreign matters included in the object of filtering.

The particle size distribution index (d25/d75) of the fine particles is preferably from 1 to 6, more preferably from 1.6 to 5, and sill more preferably from 2 to 4.

If the particle size distribution index is a preferable lower limit value or greater within the above range, the fine particles can be efficiently packed in the inner portion of the porous membrane, and thus, a flow path is easily formed, and the flow rate is improved. In addition, pores having different sizes is easily formed, and the adsorption rate of foreign matters is further improved by occurrence of different convection. d25 and d75 are values of the particle diameter having a cumulative frequencies of the particle size distribution of 75% and 25%, respectively, and in the present specification, d25 is a larger particle diameter.

In addition, in the [Formation of unbaked composite membrane] described below, in a case where an unbaked composite membrane is formed as a two-layered form, fine particles (B1) used in the first varnish and fine particles (B2) used in the second varnish may be the same as or may be different from each other. To make the pores on the side in contact with the base dense, the fine particles (B1) preferably have a particle size distribution index smaller than that of the fine particles (B2) or the same particle size distribution index. Alternatively, the fine particles (B1) preferably have sphericity smaller than that of the fine particles (B2) or the same sphericity. In addition, the fine particles (B1) preferably have a particle diameter (average diameter) of fine particles smaller than that of the fine particles (B2), and in particular, the fine particles (B1) having from 100 to 1000 nm (more preferably from 100 to 600 nm) and the fine particles (B2) having from 500 to 2000 nm (more preferably from 700 to 2000 nm) are preferably used, respectively. By using particles having a particle diameter smaller than that of the fine particles (B2) as the fine particles (B1), it is possible to increase the opening ratio of the pores on the obtained polyimide resin porous membrane surface and to make the diameter uniform, and it is possible to increase the strength of the porous membrane to be greater than that in a case where the entirety of the polyimide resin porous membrane is formed of the fine particles (B1) alone.

In the present invention, for the purpose of uniformly dispersing fine particles in the varnish, a dispersant may be further added thereto together with the fine particles. By further adding a dispersant, it is possible to more uniformly mix polyamic acid, polyimide, or polyamideimide, and fine particles, and it is possible to uniformly distribute the fine particles in an unbaked composite membrane. As a result, it is possible to provide a dense opening on the surface of the finally obtained polyimide resin porous membrane, and it is possible to efficiently form the communicating pores for communicating the rear surface of the porous membrane such that the air permeability of the polyimide resin porous membrane is improved.

The dispersant is not particularly limited, and a known dispersant can be used. Examples of the dispersant include anionic surfactants such as a coconut fatty acid salt, a castor sulfonated oil salt, a lauryl sulfate, a polyoxyalkylene allylphenyl ether sulfate, an alkylbenzene sulfonic acid, an alkylbenzene sulfonate, an alkyldiphenyl ether disulfonate, an alkylnaphthalene sulfonate, a dialkyl sulfosuccinate, an isopropyl phosphate, a polyoxyethylene alkyl ether phosphate, and a polyoxyethylene allylphenyl ether phosphate; cationic surfactants such as oleylamine acetate, laurylpyridinium chloride, cetylpyridinium chloride, lauryltrimethylammonium chloride, stearyltrimethylammonium chloride, behenyltrimethylammonium chloride, and didecyldimethylammonium chloride; amphoteric surfactants such as a coconut alkyldimethylamine oxide, a fatty acid amidopropyldimethylamine oxide, an alkylpolyaminoethylglycine hydrochloride, an amidobetaine type activator, an alanine type activator, and lauryliminodipropionic acid; polyoxyethylene octyl ether, polyoxyethylene decyl ether, polyoxyethylene lauryl ether, polyoxyethylene laurylamine, polyoxyethylene oleylamine, polyoxyethylene polystyryl phenyl ether, polyoxyalkylene polystyrylphenyl ether, other polyoxyalkylene primary alkyl ether or polyoxyalkylene secondary alkyl ether nonionic surfactants, polyoxyethylene dilaurate, polyoxyethylene laurate, polyoxyethylenated castor oil, polyoxyethylenated hydrogenated castor oil, sorbitan laurate, polyoxyethylene sorbitan laurate, fatty acid diethanolamide, other polyoxyalkylene nonionic surfactants; fatty acid alkyl esters such as octyl stearate and trimethylolpropane decanoate; and polyether polyols such as a polyoxyalkylene ether, a polyoxyalkylene oleyl ether, a trimethylolpropane tris(polyoxyalkylene) ether. As the dispersant, one type can be used, or two or more types thereof can be used in combination.

Polyamic Acid

Examples of the polyamic acid which can be used in the present invention include those obtained by polymerizing arbitray tetracarboxylic dianhydride and diamine

Tetracarboxylic Dianhydride

The tetracarboxylic dianhydride can be suitably selected from tetracarboxylic dianhydrides which are used as synthetic raw materials for polyamic acid in the related art.

The tetracarboxylic dianhydride may be an aromatic tetracarboxylic dianhydride, or may be an aliphatic tetracarboxylic dianhydride.

Examples of the aromatic tetracarboxylic dianhydride include pyromellitic dianhydride, 1,1-bis(2,3-dicarboxyphenyl)ethane dianhydride, bis(2,3-dicarboxyphenyl)methane dianhydride, bis(3,4-dicarboxyphenyl)methane dianhydride, 3,3′,4,4′-biphenyltetracarboxylic dianhydride, 2,3,3′,4 ′-biphenyltetracarboxylic dianhydride, 2,2,6,6-biphenyltetracarboxylic dianhydride, 2,2-bis(3,4-dicarboxyphenyl)propane dianhydride, 2,2-bis(2,3-dicarboxyphenyl)propane dianhydride, 2,2-bis(3,4-carboxyphenyl)-1,1,1,3,3,3-hexafluoropropane dianhydride, 2,2-bis(2,3-dicarboxyphenyl)-1,1,1,3,3 ,3-hexafluoropropane dianhydride, 3,3′,4,4-benzophenonetetracarboxylic dianhydride, bis(3,4-dicarboxyphenyl)ether dianhydride, bis(2,3-dicarboxyphenyl)ether dianhydride, 2,2′,3,3′-benzophenonetetracarboxylic dianhydride, 4,4-(p-phenyleneoxy)diphthalic dianhydride, 4,4-(m-phenylenedioxy)diphthalic dianhydride, 1,2,5 ,6-naphthalenetetracarboxylic dianhydride, 1,4,5,8-naphthalenetetracarboxylic dianhydride, 2,3,6,7-naphthalenetetracarboxylic dianhydride, 1,2,3,4-benzenetetracarboxylic dianhydride, 3,4,9,10-perylenetetracarboxylic dianhydride, 2,3,6,7-anthracenetetracarboxylic dianhydride, 1,2,7,8-phenanthrenetetracarboxylic dianhydride, 9,9-bisphthalic anhydride fluorene, and 3,3′,4,4′-diphenylsulfonetetracarboxylic dianhydride.

Examples of the aliphatic tetracarboxylic dianhydride include ethylenetetracarboxylic dianhydride, butanetetracarboxylic dianhydride, cyclopentanetetracarboxylic dianhydride, cyclohexanetetracarboxylic dianhydride, 1,2,4,5-cyclohexanetetracarboxylic dianhydride, and 1,2,3,4-cyclohexanetetracarboxylic acid dianhydride.

Among these, from the viewpoint of heat resistance of the polyimide resin to be obtained, an aromatic tetracarboxylic dianhydride is preferable. Among these, from the viewpoint of price and availability, 3,3′,4,4′-biphenyltetracarboxylic dianhydride or pyromellitic dianhydride is preferable.

As the tetracarboxylic dianhydride, one type can be used, or two or more types thereof can be used in combination.

Diamine

The diamine can be suitably selected from diamines which are used as synthetic raw materials for polyamic acid in the related art. The diamine may be an aromatic diamine, or may be an aliphatic diamine, but from the viewpoint of heat resistance of the polyimide resin to be obtained, an aromatic diamine is preferable. As the diamine, one type can be used, or two or more types thereof can be used in combination.

Examples of the aromatic diamine include a diamino compound in which about one or from 2 to 10 phenyl groups are bonded. Specific examples of the aromatic diamine include phenylenediamine or derivatives thereof, a diaminobiphenyl compound or derivatives thereof, a diaminodiphenyl compound or derivatives thereof, a diaminotriphenyl compound or derivatives thereof, diaminonaphthalene or derivatives thereof, aminophenylaminoindane or derivatives thereof, diaminotetraphenyl compound or derivatives thereof, a diaminohexaphenyl compound or derivatives thereof, and cardo type fluorenediamine derivatives.

As the phenylenediamine, m-phenylenediamine or p-phenylenediamine is preferable. As the phenylenediamine derivatives, diamines in which an alkyl group such as a methyl group or an ethyl group is bonded, for example, 2,4-diaminotoluene and 2,4-triphenylenediamine, can be given.

The diaminobiphenyl compound is a compound in which the phenyl groups in two aminophenyl groups are bonded with each other. Examples of the diaminobiphenyl compound include 4,4′-diaminobiphenyl, 4,4′-diamino-2,2′-bis(trifluoromethyl)biphenyl.

The diaminobiphenyl compound is a compound in which the phenyl groups in two aminophenyl groups are bonded with each other through other groups. Examples of the other groups include an ether bond, a sulfonyl bond, a thioether bond, an alkylene group or a derivative group thereof, an imino bond, an azo bond, a phosphineoxide bond, an amide bond, and a ureylene bond. The alkylene group preferably has about from 1 to 6 carbon atoms, and the derivative group thereof is a group in which one or more hydrogen atoms of the alkylene group are substituted with halogen atoms or the like.

Examples of the diaminodiphenyl compound include 3,3′-diaminodiphenyl ether, 3,4′-diaminodiphenyl ether, 4,4′-diaminodiphenyl ether, 3,3′-diaminodiphenyl sulfone, 3,4′-diaminodiphenyl sulfone, 4,4′-diaminodiphenyl sulfone, 3,3′-diaminodiphenyl methane, 3,4′-diaminodiphenyl methane, 4,4′-diaminodiphenyl methane, 4,4′-diaminodiphenyl sulfide, 3,3′-diaminodiphenyl ketone, 3,4′-diaminodiphenyl ketone, 2,2-bis(p-aminophenyl)propane, 2,2′-bis(p-aminophenyl)hexafluoropropane, 4-methyl-2,4-bis(p-aminophenyl)-1-pentene, 4-methyl-2,4-bis(p-aminophenyl)-2-pentene, iminodianiline, 4-methyl-2,4-bis(p-aminophenyl)pentane, bis(p-aminophenyl)phosphine oxide, 4,4′-aminoazobenzene, 4,4′-diaminodiphenyl urea, 4,4′-diaminodiphenyl amide, 1,4-bis(4-aminophenoxy)benzene, 1,3-bis(4-aminophenoxy)benzene, 1,3 -bis(3-aminophenoxy)benzene, 4,4′-bis(4-aminophenoxy)biphenyl, bis [4-(4-aminophenoxy)phenyl]sulfone, bis [4-(3-aminophenoxy)phenyl]sulfone, 2,2-bis [4-(4-aminophenoxy)phenyl]propane, and 2,2-bis [4-(4-aminophenoxy)phenyl]hexafluoropropane.

The diaminotriphenyl compound is a compound in which two aminophenyl groups and one phenylene group are bonded to with each other through respective other groups. Examples of the other groups include the same groups as the other groups in the diaminodiphenyl compound.

Examples of the diaminotriphenyl compound include 1,3-bis(m-aminophenoxy)benzene, 1,3 -bis(p-aminophenoxy)benzene, amd 1,4-bis(p-aminophenoxy)benzene.

Examples of the diaminonaphthalene include 1,5-diaminonaphthalene and 2,6-diaminonaphthalene.

Examples of the aminophenylaminoindane include 5 or 6-amino-1-(p-aminophenyl)-1,3,3-trimethylindane.

Examples of the diaminotetraphenyl compound include 4,4′-bis(p-aminophenoxy)biphenyl, 2,2′-bis [p-(p′-aminophenoxy)phenyl]propane, 2,2′-bis [p-(p′-aminophenoxy)biphenyl]propane, and 2,2′-bis [p-(m-aminophenoxy)phenyl]benzophenone.

Examples of the cardo type fluorenediamine derivatives include 9,9-bisanilinefluorene.

The aliphatic diamine preferably has, for example, about from 2 to 15 carbon atoms, and specific examples thereof include pentamethylenediamine, hexamethylenediamine, and heptamethylenediamine.

The diamine may be a compound in which the hydrogen atom has been substituted with at least one substituent selected from the group consisting of a halogen atom, a methyl group, a methoxy group, a cyano group, and a phenyl group.

Among these, as the diamine, phenylenediamine, phenylenediamine derivatives, or a diaminodiphenyl compound is preferable. Among these, from the viewpoint of price and availability, p-phenylenediamine, m-phenylenediamine, 2,4-diaminotoluene, or 4,4′-diaminodiphenyl ether is particularly preferable.

The production method of polyamic acid is not particularly limited, and for example, a known method such as a method of reacting arbitrary tetracarboxylic dianhydride with diamine in an organic solvent is used.

The reaction of tetracarboxylic dianhydride with diamine is typically performed in an organic solvent. The organic solvent used here is not particularly limited as long as it can dissolve tetracarboxylic dianhydride and diamine respectively, and does not react with tetracarboxylic dianhydride and diamine As the organic solvent, one type can be used, or two or more types thereof can be used in combination.

he organic solvent used for the reaction of tetracarboxylic dianhydride and diamine include nitrogen-containing polar solvents such as N-methyl-2-pyrrolidone, N,N-dimethylacetamide, N,N-diethylacetamide, N,N-dimethylformamide, N,N-diethylformamide, N-methylcaprolactam, and N,N,N′,N′-tetramethylurea; lactone-based polar solvents such as β-propiolactone, γ-butyrolactone, γ-valerolactone, δ-valerolactone, γ-caprolactone, and ε-caprolactone; dimethylsulfoxide; acetonitrile; fatty acid esters such as ethyl lactate and butyl lactate; ethers such as diethylene glycol dimethyl ether, diethylene glycol diethyl ether, dioxane, tetrahydrofuran, methyl cellosolve acetate, and ethyl cellosolve acetate; and phenol-based solvents such as cresols.

Among these, as the organic solvent here, a nitrogen-containing polar solvent is preferably used from the viewpoint of solubility of generated polyamic acid.

In addition, from the viewpoint of film formability or the like, a mixed solvent including a lactone-based polar solvent is preferably used. In this case, the amount of lactone-based polar solvent relative to the total weight (100% by weight) of the organic solvent is preferably from 1 to 20% by weight, and more preferably from 5 to 15% by weight.

In the organic solvent here, one or more selected from the group consisting of nitrogen-containing polar solvents and lactone-based polar solvents is preferably used, and a mixed solvent of a nitrogen-containing polar solvent and a lactone-based polar solvent is more preferably used.

The amount of organic solvent used is not particularly limited, and is preferably an amount at which the amount of the generated polyamic acid in the reaction solution after the reaction becomes about from 5 to 50% by weight.

Each amount of tetracarboxylic dianhydride and diamine used is not particularly limited, and from 0.50 to 1.50 moles of diamine relative to 1 mole of tetracarboxylic acid dianhydride is preferably used, from 0.60 to 1.30 moles is more preferably used, and from 0.70 to 1.20 moles is particularly preferably used.

The reaction (polymerization) temperature is generally from −10 to 120° C., and preferably from 5 to 30° C. The reaction (polymerization) time varies depending on the raw material composition used, but is typically from 3 to 24 (hours).

In addition, the intrinsic viscosity of the polyamic acid solution obtained under these conditions is preferably within a range of from 1000 to 100000 cP (centipoise) (from 1 to 100 Pa·s), and more preferably within a range of from 5000 to 70000 cP (from 5 to 70 Pa·s).

The intrinsic viscosity of the polyamic acid solution can be measured under a temperature condition of 25·C using an E type rotational viscometer.

Polyimide

The polyimide which can be used in the present invention is not limited to the structure and the molecular weight thereof as long as it can be dissolved in the organic solvent used in a varnish, and a known polyimide can be used.

Polyimide may have a condensable functional group such as a carboxy group on the side chain or a functional group promoting a cross-linking reaction or the like at the time of baking.

To obtain polyimide soluble in the organic solvent used in a varnish, the use of a monomer for introducing a flexible bend structure in the main chain is effective. Examples of the monomer include aliphatic diamines such as ethylenediamine, hexamethylenediamine, 1,4-diaminocyclohexane, 1,3-diaminocyclohexane, and 4,4′-diaminodicyclohexylmethane; aromatic diamines such as 2-methyl-1,4-phenylenediamine, o-tolidine, m-tolidine, 3,3′-dimethoxybenzidine, and 4,4′-diaminobenzanilide; polyoxyalkylenediamines such as polyoxyethylenediamine, polyoxypropylenediamine, and polyoxybutylenediamine; polysiloxanediamine; and 2,3,3′,4′-oxydiphthalic anhydride, 3,4,3′,4′-oxydiphthalic anhydride, and 2,2-bis(4-hydroxyphenyl)propane dibenzoate-3,3′,4,4′-tetracarboxylic dianhydride.

In addition, it is also effective to use a monomer having a functional group which improves the solubility in the organic solvent. Examples of the monomer having such a functional group include fluorinated diamines such as 2,2′-bis(trifluoromethyl)-4,4′-diaminobiphenyl and 2-trifluoromethyl-1,4-phenylenediamine

Furthermore, in addition to the monomer having such a functional group, the monomers exemplified in the description of the above-described polyamic acid can also be used in combination within a range not impairing the solubility.

The production method of polyimide is not particularly limited, and for example, a known method such as a method of chemically imidizing or thermally imidizing polyamic acid and of dissolving the resulting product in an organic solvent can be given.

Examples of the polyimide which can be used in the present invention include aliphatic polyimides (entire aliphatic polyimides) and aromatic polyimides, and among these, aliphatic polyimides are preferable.

The aromatic polyimide may be an aromatic polyimide obtained by thermally or chemically ring-closing reaction of polyamic acid having a structural unit represented by the following General Formula (5) or an aromatic polyimide obtained by dissolving polyimide having a structural unit represented by the following General Formula (6) in a solvent.

In the formula, R_{Ar} represents an aryl group, and R′_{Ar} represents an arylene group.

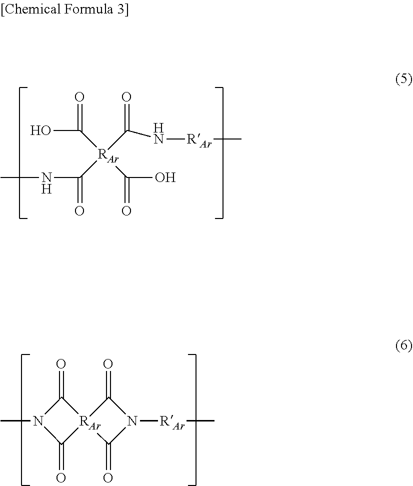

In the formula, R_{Ar} is not particularly limited as long as it is a cyclic conjugated system having 4n+2π (electrons, and may be monocyclic or polycyclic. The aromatic ring preferably has 5 to 30 carbon atoms, more preferably 5 to 20, still more preferably 6 to 15, and most preferably 6 to 12. Examples of the aromatic ring include aromatic hydrocarbon rings, such as benzene, naphthalene, anthracene and phenanthrene; and aromatic hetero rings in which part of the carbon atoms constituting the aforementioned aromatic hydrocarbon rings has been substituted with a hetero atom. Examples of the hetero atom within the aromatic hetero rings include an oxygen atom, a sulfur atom and a nitrogen atom. Specific examples of the aromatic hetero ring include a pyridine ring and a thiophene ring. Among these examples, as R_{Ar}, an aromatic hydrocarbon ring is preferable, benzene or naphthalene is more preferable, and benzene is particularly preferable.

In the above formulae, examples of R′_{Ar} include a group obtained by removing two hydrogen atoms from the aromatic ring in R_{Ar}. Among these examples, as R′_{Ar}, a group obtained by removing two hydrogen atoms from an aromatic hydrocarbon ring is preferable, a group obtained by removing two hydrogen atoms from benzene or naphthalene is more preferable, and a phenylene group obtained by removing two hydrogen atoms from benzene is particularly preferable.

The aryl group represented by R_{Ar} and the arylene group represented by R′_{Ar} may have a substituent, respectively.

Polyamideimide

The polyamideimide which can be used in the present invention is not limited to the structure and the molecular weight thereof as long as it can be dissolved in the organic solvent used in a varnish, and a known polyamideimide can be used.

Polyamideimide may have a condensable functional group such as a carboxy group on the side chain or a functional group promoting a cross-linking reaction or the like at the time of baking.

As the polyamideimide, polyamideimide obtained by a reaction of arbitrary trimellitic anhydride with diisocyanate or polyamideimide obtained by imidizing the precursor polymer obtained by a reaction of a reactive derivative of arbitrary trimellitic anhydride with a diamine can be used without particular limitation.

Examples of the reactive derivative of the arbitrary trimellitic anhydride include trimellitic anhydride halides such as trimellitic anhydride chloride and trimellitic anhydride esters.

Examples of the arbitrary diisocyanates include meta-phenylene diisocyanate, p-phenylene diisocyanate, o-tolidine diisocyanate, p-phenylene diisocyanate, m-phenylene diisocyanate, 4,4′-oxybis(phenylisocyanate), 4,4′-diisocyanatodiphenylmethane, bis [4-(4-isocyanatephenoxy)phenyl]sulfone, 2,2′-bis[4-(4-isocyanatephenoxy)phenyl]propane, 2,4-tolylene diisocyanate, 2,6-tolylene diisocyanate, 4,4′-diphenylmethane diisocyanate, 3,3′-dimethyldiphenyl-4,4′-diisocyanate, 3,3′-diethyldiphenyl-4,4′-diisocyanate, isophorone diisocyanate, hexamethylene diisocyanate, 4,4′-dicyclohexylmethane diisocyanate, m-xylene diisocyanate, p-xylene diisocyanate, and naphthalene diisocyanate.

Examples of the above-described arbitrary diamine include the same diamines as those exemplified in the description of the above-described polyamic acid.

Organic Solvent

The organic solvent which can be used in the preparation of varnishes is not particularly limited as long as it is possible to dissolve polyamic acid and/or a polyimide resin and does not dissolve the fine particles, and examples thereof include the same organic solvents as those used in the reaction of tetracarboxylic dianhydride and diamine As the organic solvent, one type can be used, or two or more types thereof can be used in combination.

The amount of the organic solvent in the varnish is preferably from 50 to 95% by weight, and more preferably from 60 to 85% by weight. The concentration of the solid content in the varnish is preferably from 5 to 50% by weight, and more preferably from 15 to 40% by weight.

In addition, in the [Formation of unbaked composite membrane] described below, in a case where an unbaked composite membrane is formed as a two-layered form, the volume ratio between polyamic acid, polyimide, or the polyamideimide (A1), and the fine particles (B1) in the first varnish is preferably from 19:81 to 45:55. In a case where the total is 100, if the volume proportion of the fine particles (B1) is 55 or greater, the particles are uniformly dispersed, and if the volume proportion is 81 or less, the particles are easily dispersed without agglomeration of the particles. Thus, pores can be uniformly formed on the surface side of the base side of the polyimide resin molded membrane.

In addition, the volume ratio between polyamic acid, polyimide, or a polyamideimide (A2), and the fine particles (B2) in the second varnish is preferably from 20:80 to 50:50. In a case where the total is 100, if the volume proportion of the fine particles (B2) is 50 or greater, the particle simple substances are likely to be uniformly dispersed, and if the volume proportion is 80 or less, the particles do not agglomerate to each other, and cracks hardly occur on the surface. Thus, a polyimide resin porous membrane having good mechanical characteristics such as stress, breaking elongation, and the like is likely to be formed.

For the volume ratio, the second varnish preferably has a fine particles-containing ratio lower than that of the first varnish. By satisfying the above conditions, even in a case where the fine particles are highly packed in polyamic acid, polyimide, or polyamideimide, the strength and the flexibility of an unbaked composite membrane, a polyimide resin-fine particle composite membrane, and a polyimide resin porous membrane are ensured. In addition, by providing a layer having a low fine particles-containing ratio, the production cost can be reduced.

When preparing a varnish, in addition to the components described above, known components such as an antistatic agent, a flame retardant, a chemically imidizing agent, a condensing agent, a release agent, and a surface conditioner can be mixed in, if necessary, for the purpose of preventing static charge, imparting flame retardancy, low-temperature baking, releasability, coating properties, and the like.

[Formation of Unbaked Composite Membrane]

The formation of an unbaked composite membrane containing polyamic acid, polyimide, or polyamideimide, and fine particles, for example, is performed by applying the varnish to a base and by drying at atmospheric pressure or in vacuum under a condition of from 0 to 120° C. (preferably from 0 to 100° C.), and more preferably at atmospheric pressure under a condition of from 60 to 95° C. (still more preferably from 65 to 90° C.). The coating film thickness, for example, is preferably from 1 to 500 μm, and more preferably from 5 to 50 μm.

A release layer may be provided on a base, if necessary. In addition, in the formation of an unbaked composite membrane, before the [Baking of unbaked composite membrane] described below, an immersing step in a solvent including water, a drying step, and a pressing step may be provided as an optional step, respectively.

The above-described release layer can be manufactured by performing applying a release agent to a base and drying or baking the resulting product. As the release agent used here, a known release agent such as an alkyl phosphoric acid ammonium salt-based release agent, a fluorine-based release agent, or a silicone-based release agent can be used without particular limitation. When peeling off an unbaked composite membrane after drying from the base, a slight amount of release agent remains on the release surface of the unbaked composite membrane. Since the remaining release agent can affect the wettability of the polyimide resin porous membrane surface or impurities mixing, this is preferably removed.

Therefore, the unbaked composite membrane peeled off from the base is preferably washed with an organic solvent or the like. As the washing method, known methods such as a method of removing after the unbaked composite membrane is immersed in a washing liquid and a method of shower washing can be given.

To dry the unbaked composite membrane after washing, for example, the unbaked composite membrane after washing is air-dried at room temperature or is warmed to a suitable set temperature in a thermostat. At this time, for example, it is also possible to adopt a method of preventing deformation by fixing the end portions of the unbaked composite membrane to a mold made of SUS or the like.

On the other hand, in the formation of an unbaked composite membrane, in a case where a base that is not provided with a release layer is used, a step of forming the release layer or a step of washing the unbaked composite membrane can be omitted.

In addition, in a case where an unbaked composite membrane is formed in a two-layered form, formation of a first unbaked composite membrane having a membrane thickness of from 1 to 5 μm is performed by, first, applying the first varnish to a base such as a glass substrate, and by drying at atmospheric pressure or in vacuum under a condition of from 0 to 120° C. (preferably from 0 to 90° C.), and more preferably at atmospheric pressure under a condition of from 10 to 100° C. (still more preferably from 10 to 90° C.).

Subsequently, a two-layered unbaked composite membrane can be formed by performing formation of a second unbaked composite membrane having a membrane thickness of 5 to 50 μm by applying the second varnish to the first unbaked composite membrane, and in the same manner, by drying at from 0 to 80° C. (preferably from 0 to 50° C.) and more preferably at atmospheric pressure under a condition of from 10 to 80° C. (still more preferably from 10 to 30° C.).

[Baking of Unbaked Composite Membrane]

By performing a heat treatment (baking) on the unbaked composite membrane after the above [Formation of unbaked composite membrane], a composite membrane (polyimide resin-fine particle composite membrane) formed of a polyimide resin and fine particles is formed.

In the case of including polyamic acid in the varnish, in the [Baking of unbaked composite membrane] in this step, it is preferable to complete the imidization.

The temperature (baking temperature) of the heat treatment varies depending on the presence or absence of the structure of polyamic acid, polyimide, or polyamideimide contained in the unbaked composite membrane and a condensing agent, and is preferably from 120 to 400° C., and more preferably from 150 to 375° C.

It is not always necessary to clearly divide the drying in the previous step and the operation to perform the baking. For example, in a case where baking is performed at 375° C., a method of raising the temperature from room temperature to 375° C. for 3 hours and then holding at 375° C. for 20 minutes, or a stepwise drying-thermal imidization method of raising (holding for 20 minutes at each stage) the temperature stepwise to 375° C. with a 50° C. increment from room temperature and finally holding at 375° C. for 20 minutes can also be used. At this time, a method of preventing deformation by fixing the end portions of the unbaked composite membrane to a mold made of SUS or the like may be adopted.

The thickness of the polyimide resin-fine particle composite membrane after the heat treatment (baking), for example, is preferably 1μm or greater, more preferably from 5 to 500 μm, and still more preferably from 8 to 100 μm.

The thickness of the polyimide resin-fine particle composite membrane can be determined by measuring the thickness of a plurality of positions using a micrometer and by averaging these.

This step is an optional step. In particular, in a case where polyimide or polyamideimide is used in varnish, this step may not be performed.

[Removal of Fine Particles]

By removing the fine particles from the non-polyimide resin-fine particle composite membrane after the above [Baking of unbaked composite membrane], a polyimide resin porous membrane is produced.

For example, in a case where silica is adopted as fine particles, by the polyimide resin-fine particle composite membrane coming into contact with hydrogen fluoride (HF) water having a low concentration, the silica is dissolved and removed, and a porous membrane is obtained. In addition, in a case where the fine particles are resin fine particles, by heating at the thermal decomposition temperature of the resin particles or higher and at a temperature lower than the thermal decomposition temperature of the polyimide resin, the resin fine particles are decomposed and removed, and a porous membrane is obtained.

[Etching (Ring-Opening of Imide Bond)]

The etching step can be performed by a chemical etching method or a physical removal method, or a combined method thereof.

For Chemical Etching Method

As the chemical etching method, a conventionally known method can be used.

The chemical etching method is not particularly limited, and treatments with an etching liquid such as an inorganic alkali solution or an organic alkaline solution can be given. Among these, a treatment with an inorganic alkali solution is preferable.

Examples of the inorganic alkali solution include a hydrazine solution including hydrazine hydrate and ethylenediamine; a solution of an alkali metal hydroxide such as potassium hydroxide, sodium hydroxide, sodium carbonate, sodium silicate, or sodium metasilicate; an ammonia solution; and an etching liquid mainly having alkali hydroxide, hydrazine, and 1,3-dimethyl-2-imidazolidinone.

Examples of the organic alkali solution include alkaline etching liquids of primary amines such as ethylamine and n-propylamine; secondary amines such as diethylamine and di-n-butylamine; tertiary amines such as triethylamine and methyldiethylamine; alcohol amines such as dimethylethanolamine and triethanolamine; quaternary ammonium salts such as tetramethylammonium hydroxide and tetraethylammonium hydroxide; and cyclic amines such as pyrrole and piperidine. The alkali concentration in the etching liquid, for example, is from 0.01 to 20% by weight.

The solvent of each etching liquid described above can be suitably selected from pure water and alcohols, and a solvent in which a suitable amount of surfactant has been added can also be used.

For Physical Removal Method

As the physical removal method, for example, a dry etching method by plasma (oxygen, argon, or the like), corona discharge, or the like can be used.

The chemical etching method or the physical removal method described above can also be applied before the above [Removal of fine particles], or can also be applied after the above [Removal of fine particles].

Among these, from the viewpoint of the fact that the communicating pores inside the polyimide resin porous membrane are more easily formed, and the removability of foreign matters is increased, it is preferable to apply after the above [Removal of fine particles].

In a case where the chemical etching method is performed in the etching step, to remove the excessive etching liquid, the step of washing the polyimide resin porous membrane may be provided after this step.

Washing after the chemical etching may be performed with water alone, and it is preferable to combine washing with an acid and washing with water.

In addition, after the etching step, for wettability improvement to an organic solvent of the polyimide resin porous membrane surface and the remaining organic material removal, a heat treatment (rebaking) may be performed on the polyimide resin porous membrane. The heating conditions are the same as conditions in the above

[Baking of Unbaked Composite Membrane].

For example, in the polyimide resin porous membrane produced by the production method described above, the spherical cells and the communicating pores through which the adjacent spherical cells are mutually communicating are formed, and the porous membrane preferably has communicating pores by which a flow path through which a fluid can pass the porous membrane by the communicating pores which are open on the external surface of one side communicating with the inside of the porous membrane and by being open on the external surface of the other side (back side) is secured.

The Gurley air permeability of the “porous membrane in which adjacent spherical cells are mutually communicating”, for example, is preferably 30 seconds or longer from the viewpoint of the fact that the flow rate of an object of filtering passing through the porous membrane is maintained at a high level to some extent and removal of the foreign matters is efficiently performed. The Gurley air permeability of the polyimide resin porous membrane is more preferably from 30 to 1000 seconds, still more preferably from 30 to 600 seconds, particularly preferably from 30 to 500 seconds, and most preferably from 30 to 300 seconds. If the Gurley air permeability is a preferable upper limit value or less within the above range, the degree of porosity (abundance ratio of communicating pores) is sufficiently high, and thus, the effects of removal of foreign matters are more easily obtained.

The Gurley air permeability of the polyimide resin porous membrane can be measured according to JIS P 8117.

The “porous membrane in which adjacent spherical cells are mutually communicating” preferably includes communicating pores of which the pore diameter is from 1 to 200 nm, more preferably from 3 to 180 nm, still more preferably from 5 to 150 nm, and particularly preferably from 10 to 130 nm.

The pore diameter of the communicating pores means the diameter of the communicating pores. Since one communicating pore is formed from typical two adjacent particles by the production method described above, for example, if the direction in which two pores constituting communicating pores are adjacent is a longitudinal direction, in the diameter, a case where a diameter is in the direction perpendicular to the longitudinal direction is included.

In a case where the etching step (ring-opening of an imide bond) described above is not provided, the pore diameter of the communicating pores tends to be reduced.

In addition, the average pore diameter of the “porous membrane in which adjacent spherical cells are mutually communicating” is preferably from 100 to 2000 nm, more preferably from 200 to 1000 nm, and still more preferably from 300 to 900 nm.

The average pore diameter of the porous membrane is a value obtained by measuring the diameter of the communicating pore of a porous membrane (e.g., a polyimide porous membrane) subjected to the chemical etching described above on the basis of a bubble point method using a perm porometer (e.g., Porous Materials INC.). For the porous membrane (e.g., polyamideimide porous membrane) on which the chemical etching has not been performed, the average particle diameter of the fine particles used in the production of a porous membrane is an average pore diameter.

The “porous membrane in which adjacent spherical cells are mutually communicating”, as described above, is preferably a porous membrane containing pores having an average pore diameter of several hundreds of nanometers. Thus, for example, even microsubstances of a nanometer unit can be adsorbed or trapped in the pores and/or communicating pores in the porous membrane.

For the pore diameter of the communicating pores, the distribution of pore diameters of respective pores imparting porosity to the “porous membrane in which adjacent spherical cells are mutually communicating” becomes broad, and the pore diameter of the communicating pores formed of adjacent pores tends to be reduced.

From the viewpoint of reducing the pore diameter of the communicating pores, the porosity of the “porous membrane in which adjacent spherical cells are mutually communicating”, for example, is preferably 50% by weight or greater, more preferably from 60 to 90% by weight, still more preferably from 60 to 80% by weight, and particularly preferably about 70% by weight. If the porosity is a preferable lower limit value or greater within the above range, the effects of removal of foreign matters are more easily obtained. If the porosity is a preferable upper limit value or less within the above range, the strength of the porous membrane is further enhanced.

The porosity of the polyimide resin porous membrane is determined by calculating the ratio of the weight of the fine particles relative to the total weight of the resin and the fine particles used in the production of the porous membrane.

In addition, the “porous membrane in which adjacent spherical cells are mutually communicating” preferably includes communicating pores having an average pore diameter of 0.01 to 50 nm as determined by the BET method, and more preferably 0.05 to 10 nm. The average pore diameter of the communicating pore is more preferably 0.1 to 40 nm, still more preferably 1 to 30 nm, and most preferably 1 to 20 nm.

By virtue of having communicating pores having an average pore diameter as determined by the BET method within the above-mentioned range, a high molecular weight substance (for example, a molecule having a molecular weight of 30,000 or more in the molecular weight distribution) that may cause defects in the s pattern can be effectively reduced in a resin used in a semiconductor manufacturing process.

The BET method is a method of measuring an adsorption isotherm by adsorbing and desorbing an adsorbable molecule (for example, nitrogen) on a porous body, and analyzing the measured data based on the BET equation represented by the following formula (Bel). Based on this method, the specific surface area A and the total pore volume V can be calculated, and further, the average pore diameter can be calculated from the formula [4V/A] based on the obtained specific surface area A and the total pore volume V.

Specifically, first, the adsorption isotherm is obtained by adsorbing and desorbing adsorbable molecules on the porous body. Then, from the obtained adsorption isotherm, [P/{Va(P0-P)}] is calculated based on the following formula (B1) and plotted against the equilibrium relative pressure (P/P0). Then, regarding this plot as a straight line, the slope s (=[(C−1)/(Vm·C)]) and the intercept i (=[1/(Vm·C)]) are calculated based on the least squares method. Then, Vm and C are calculated from the obtained slope s and intercept i based on the formula (Be2-1) and the formula (B2-2). Furthermore, the specific surface area A can be calculated from Vm based on the formula (Be3). Further, the obtained adsorption isotherm adsorption data is linearly interpolated to obtain the adsorption amount at the relative pressure set by the pore volume calculation relative pressure. The total pore volume V can be calculated from this adsorption amount. The BET method is a measuring method according to JIS R1626-1996 “Method for measuring specific surface area of fine ceramic powder by gas adsorption BET method”. The measuring device according to the BET method is not particularly limited, but examples include Micromeritics (manufactured by Shimadzu Corporation).

[P/{Vₐ(P₀−P)}]=[1/(Vₘ·C)]+[(C−1)/(Vₘ·C)](P/P₀) (1)

Vₘ=1/(s+i) (2-1)

C=(s/i)+1 (2-2)

A=(Vₘ·L·σ)/22414 (3)

Va: Adsorption amount

Vm: Adsorption amount of monolayer

P: Pressure at equilibrium of adsorbed molecules

P0: Saturated vapor pressure of adsorbed molecule

L: Avogadro's number

σ: Adsorption cross-sectional area of adsorbed molecule

The “porous membrane in which adjacent spherical cells are mutually communicating” is excellent in mechanical characteristics such as stress and breaking elongation.

The stress of the “porous membrane in which adjacent spherical cells are mutually communicating” of the filter, for example, is preferably 10 MPa or greater, more preferably 15 MPa or greater, and still more preferably from 15 to 50 MPa. The stress of the porous membrane is a value measured under the measurement conditions of 5 mm/min using a tester after a sample having a size of 4 mm×30 mm is manufactured.

In addition, the breaking elongation of the “porous membrane in which adjacent spherical cells are mutually communicating”, for example, is preferably 10% GL or greater, and more preferably 15% GL or greater. The upper limit of the breaking elongation is preferably 50% GL or less, more preferably 45% GL or less, and still more preferably 40% GL or less. As the porosity of the polyimide resin porous membrane is lowered, the breaking elongation tends to become higher.

The breaking elongation of the porous membrane is a value measured under the measurement conditions of 5 mm/min using a tester after a sample having a size of 4 mm×30 mm is manufactured.

The thermal decomposition temperature of the “porous membrane in which adjacent spherical cells are mutually communicating” is preferably 200° C. or higher, more preferably 320° C. or higher, and still more preferably 350° C. or higher. The thermal decomposition temperature of the polyimide resin porous membrane can be measured by raising the temperature to 1000° C. at a temperature raising rate of 10° C./min in an air environment.

The filter in the present aspect is not limited to a filter provided with a porous membrane in which a communicating pore 5 through which the spherical cell 1a and the spherical cells 1b adjacent as shown in FIG. 1 comprising are communicating is formed, and in addition to the communicating pore 5, the filter may provided with a porous membrane in which other forms of cells or communicating pores are formed. As other forms of cells (hereinafter, this is referred as “other cells”), cells having a different shape or pore diameter can be given, and examples thereof include ellipse shape cells, polyhedral cells, and spherical cells having a different pore diameter. As the “other forms of communicating pores” described above, for example, communicating pores through which spherical cells and other cells are communicating can be given.

The shape or pore diameter of the other cells may be suitably determined depending on the type of impurities which are removal targets. The communicating pores through which spherical cells and other cells are communicating are formed by selecting the material of the above-described fine particles, or by controlling the shape of the fine particles.

In addition to the communicating pores through which adjacent spherical cells are mutually communicating, according to the filter provided with a porous membrane in which other forms of cells or communicating pores are formed, various types of foreign matters are more efficiently removed from an object of filtering.

In addition, the filter according to the present embodiment may replace the filter cartridge or the like for removing the fine particle impurities installed in the related art in the supply line or point of use (POU) of various chemical liquid in the semiconductor production process, an can be used in combination therewith. Therefore, by the exactly same apparatus and operation in the related art, various foreign matters can be efficiently removed from the object for filtering, and purified product of a resin composition for forming a phase-separated structure can be produced with high purity.

«Filtration of resin composition for forming phase-separated structure»

The filtration of a resin composition for forming a phase-separated structure using a filter provided with a porous membrane in which adjacent spherical cells are mutually communicating may be performed in a state without a pressure difference (i.e., a liquid chemical for lithography may be passed through by gravity only with respect to the filtration filter), or may be performed in a state in which a pressure difference is applied. Among these, the latter is preferable, and an operation of allowing a resin composition for forming a phase-separated structure to pass through a filtration filter by pressure difference is preferably performed.

The “state in which a pressure difference is applied” means that there is a pressure difference between the one side and the other side of the polyimide resin porous membrane provided in the filter.

For example, the pressurization (positive pressure) which is a pressure applied to one side (supplying side of a resin composition for forming a phase-separated structure) of the polyimide resin porous membrane and the reduced pressure (negative pressure) which makes one side (filtrate side) of the polyimide resin porous membrane a minus pressure can be given. In the filtration step in the present embodiment, the former, that is, the pressurization, is preferable.

The pressurization is that pressure is applied to the feed solution side of the polyimide resin porous membrane in which a resist composition (hereinafter, referred to as the “feed solution”) before passing the polyimide resin porous membrane is present.

For example, utilizing the flow fluid pressure occurring in circulation or feeding flow of a feed solution or by utilizing a positive pressure of gas, pressure is preferably applied to the feed solution side.

The flow fluid pressure can be generated, for example, by an aggressive flow fluid pressure application method of a pump (a feeding flow pump, a circulation pump, or the like). Examples of the pump include a rotary pump, a diaphragm pump, a metering pump, a chemical pump, a plunger pump, a bellows pump, a gear pump, a vacuum pump, an air pump, and a liquid pump.

In a case where circulation or feeding of the feed solution by a pump is performed, typically, the pump is disposed between the feed solution tank (or circulation vessel) and the polyimide resin porous membrane.

When a feed solution is passed through the polyimide resin porous membrane by gravity only, the flow fluid pressure, for example, may be a pressure applied to the polyimide resin porous membrane by the feed solution, but is preferably a pressure applied by the aggressive flow fluid pressure application method described above. As the gas used for pressurization, a gas inert or non-reactive with respect to the feed solution is preferable, and specifically, noble gases such as nitrogen, helium, and argon can be given.

As a method of applying pressure to the feed solution side, it is preferable to use a positive pressure of gas. At that time, the filtrate side which has passed through the polyimide resin porous membrane may be atmospheric pressure without performing reduction of pressure.

In addition, pressurization may be one that utilizes both a flow fluid pressure and a positive pressure of gas. In addition, the pressure difference may be combination of pressurization and pressure reduction, and for example, may be one utilizing both a flow fluid pressure and reduced pressure, one utilizing both a positive pressure of gas and reduced pressure, or one utilizing a flow fluid pressure, a positive pressure of gas, and reduced pressure. In the case of combining methods of providing a pressure difference, from the viewpoint of convenience of production, combination of a flow fluid pressure and a positive pressure of gas or combination of a flow fluid pressure and pressure reduction is preferable.

In the present embodiment, from the viewpoint of suing the polyimide resin porous membrane, the method of providing a pressure difference, for example, may be a one method such as a positive pressure by gas, and has excellent foreign matter removal performance.

The pressure reduction is to depressurize the filtrate side which has passed through the polyimide resin porous membrane, and for example, may be pressure reduction by a pump, and it is preferable to reduce the pressure to vacuum.

In the case of performing an operation in which a resin composition for forming a phase-separated structure is passed through a filtration filter in the state in which a pressure difference is provided, the pressure difference is suitably set in consideration of the film thickness of the polyimide resin porous membrane used, the porosity or the average pore diameter, the desired purity, the amount of fluid flowing, the flow rate, or the concentration or the viscosity of a feed solution. For example, the pressure difference in the case of a so-called cross flow method (feed solution flows parallel to the polyimide resin porous membrane), for example, is preferably 0.3 MPa or less.

The pressure difference in the case of a so-called dead-end method (feed solution flows to intersect the polyimide resin porous membrane), for example, is preferably 1 MPa or less, and more preferably 0.3 MPa or less. The lower limit value of each of the pressure differences is not particularly limited, and for example, is preferably 0.01MPa or greater, and more preferably 0.05MPa or greater.

The operation in which a resin composition for forming a phase-separated structure is passed through a filtration filter provided with the polyimide resin porous membrane can be performed in a state in which the flow rate of the resin composition for forming a phase-separated structure (feed solution) is maintained to be high.

The flow rate in this case is not particularly limited, and for example, the flow rate of pure water in the case of being pressurized to 0.08 MPa at room temperature (20° C.) is preferably 1 mL/min or greater, more preferably 3 mL/in or greater, still more preferably 5 mL/min or greater, and particularly preferably 10 mL/min or greater. The upper limit value of the flow rate is not particularly limited, and for example, is 50 mL/min or less.

In the present embodiment, since the filter having the polyimide resin porous membrane described above is used, it is possible to perform filtration while maintaining a high flow rate, and the removal ratio of the foreign matters included in the resin composition for forming a phase-separated structure can be increased.

In addition, in step (i), an operation in which a resin composition for forming a phase-separated structure is passed through a filter is preferably performed by setting the temperature of the resin composition for forming a phase-separated structure to from 0 to 30° C., and more preferably setting to from 5 to 25° C.

In addition, in step (i), the resin composition for forming a phase-separated structure may be passed through a filter provided with the polyimide resin porous membrane a plurality of times (circulation filtration may be conducted a plurality of times), or may be passed through a plurality of filtration filters, including at least a filtration filter provided with the polyimide resin porous membrane.

Further, to wash the polyimide resin porous membrane, improve wettability with respect to the feed solution, or adjust the surface energy of the polyimide resin porous membrane and the feed solution before the feed solution is passed through the polyimide resin porous membrane, an alcohol such as methanol, ethanol, or isopropyl alcohol, a ketone such as acetone or methyl ethyl ketone, water, or a solution of a solvent included in a feed solution or mixtures thereof may be passed through by bring into contact with the polyimide resin porous membrane. To bring the above solution into contact with the polyimide resin porous membrane, the polyimide resin porous membrane may be impregnated into the solution, or may be immersed. By bring the above solution into contact with the polyimide resin porous membrane, for example, it is possible to penetrate the solution into the pores in the inside of the polyimide resin porous membrane. Contact between the above solution and the polyimide resin porous membrane may be performed in a state in which the above-described pressure difference is provided, and in particular, in the case of making the solution penetrate also into the pores in the inside of the polyimide resin porous membrane, contact is preferably performed under pressure.

<Other Steps>

The production method according to the present embodiment may include other steps in addition to the step (i). Examples of the other step include a step of filtering with a filter other than the filter including the polyimide resin porous membrane. The filters other than the filter including the polyimide resin porous membrane are not particularly limited, and examples thereof include a filter provided with a porous membrane of a thermoplastic resin, such as polyamide membranes such as nylon membranes, polyethylene membranes, polypropylene membranes, polytetrafluoroethylene (PTFE) membranes, tetrafluoroethylene-perfluoroalkyl vinyl ether copolymer (PFA) membrane, and any of these membranes modified. Among these examples, it is preferable to use, as the other filter, a filter having a porous membrane containing a polyamide resin and/or a filter having a porous membrane containing a polyethylene resin as the other filter because of excellent foreign matter removal performance. It is more preferable to use a filter provided with a porous membrane containing a polyamide resin.

«Step (iia)»

The production method according to the present embodiment preferably further includes, in addition to the step (i), a step (iia) of filtering with a filter provided with a porous membrane containing a polyamide resin. The porous membrane containing a polyamide resin (hereinafter also referred to as “polyamide resin porous membrane”) may be made of only a polyamide resin, or may contain a polyamide resin and another resin. It is preferable to use a porous membrane made of only a polyamide resin.

The polyamide resin porous membrane is not particularly limited, and conventionally known membranes can be used. Since the polyamide resin porous membrane is excellent in versatility, it is preferable to use a nylon 6 and/or nylon 66 porous membrane, and it is more preferable to use a nylon 66 porous membrane. The average pore diameter of the polyamide resin porous membrane is not particularly limited, but from the viewpoint of removing fine foreign matter, 0.1 to 100 nm is preferable, 0.3 to 50 nm is more preferable, and 0.5 to 10 nm is still more preferable.

As a filter provided with such a polyamide resin porous membrane, a filter in which a polyamide resin porous membrane is provided on an outer container made of a thermoplastic resin (polyethylene, polypropylene, PFA, polyether sulfone (PES), polyimide, polyamide imide, or the like) may be mentioned.

The step (iia) may be performed before the step (i) or after the step (i).

The step (iia) is preferably performed after the step (i). In this case, the average pore diameter of the polyamide resin porous membrane is preferably smaller than the average pore diameter of the communicating pores of the polyimide porous membrane.

In the production method of the present embodiment, an operation of conducting the step (iia) after the step (i) may be repeated. In this case, the resin composition for forming a phase-separated structure (supply liquid) is constantly circulated and passed through a filter having a polyimide resin porous membrane and a filter having a polyamide resin porous membrane. In the case of performing the circulation filtration as described above, it is preferable that, in the circulation path, both filters are arranged such that the resin composition for forming a phase-separated structure passes the polyamide resin porous membrane after the phase separation structure forming resin composition has passed through the filter having a polyimide resin porous membrane.

When performing the step (iia), as in the step (i), to wash the polyamide resin porous membrane, improve wettability with respect to the feed solution, or adjust the surface energy of the polyamide resin porous membrane and the feed solution before the feed solution is passed through the polyamide resin porous membrane, an alcohol such as methanol, ethanol, or isopropyl alcohol, a ketone such as acetone or methyl ethyl ketone, water, or a solution of a solvent included in a feed solution or mixtures thereof may be passed through by bring into contact with the polyamide resin porous membrane.

«Step (iib)»

In the production method according to the present embodiment, in addition to the step (i), or in addition to the steps (i) and (iia), it is preferable to further include a step (iib) of filtering with a filter provided with a porous membrane containing a polyethylene resin.

The porous membrane containing a polyethylene resin (hereinafter also referred to as “polyethylene resin porous membrane”) may be made of only a polyethylene resin or may contain a polyethylene resin and another resin. It is preferable that the porous membrane is made of only polyethylene resin.

The polyethylene resin porous membrane is not particularly limited, and conventionally known membranes can be used. As the polyethylene resin porous film, it is preferable to use an ultra high molecular weight polyethylene (UPE) porous film because it has excellent impact resistance, abrasion resistance, and chemical resistance.

The average pore diameter of the polyethylene resin porous membrane is not particularly limited, but from the viewpoint of removing fine foreign matter, 0.1 to 100 nm is preferable, 0.3 to 50 nm is more preferable, and 0.5 to 10 nm is still more preferable.

As a filter provided with such a polyethylene resin porous membrane, a filter in which a polyethylene resin porous membrane is provided on an outer container made of a thermoplastic resin (polyethylene, polypropylene, PFA, polyether sulfone (PES), polyimide, polyamide imide, or the like) may be mentioned.

The step (iib) may be performed before the step (i) or after the step (i).

Further, when the step (iia) is performed, the step (iib) may be performed before the step (iia) or after the step (iia), but is preferably performed after the step (iia). It is more preferable to perform the step (i), the step (iia) and the step (iib) in this order.

In the step (iib), the average pore diameter of the polyethylene resin porous membrane is preferably smaller than the average pore diameter of the communicating pores of the polyimide porous membrane.

In the production method of the present embodiment, an operation of conducting the step (iib) after the step (i) may be repeated. In this case, the resin composition for forming a phase-separated structure (supply liquid) is constantly circulated and passed through a filter having a polyimide resin porous membrane and a filter having a polyethylene resin porous membrane. In the case of performing the circulation filtration as described above, it is preferable that, in the circulation path, both filters are arranged such that the resin composition for forming a phase-separated structure passes the polyethylene resin porous membrane after the phase separation structure forming resin composition has passed through the filter having a polyimide resin porous membrane.

When performing the step (iib), as in the step (i), to wash the polyethylene resin porous membrane, improve wettability with respect to the feed solution, or adjust the surface energy of the polyethylene resin porous membrane and the feed solution before the feed solution is passed through the polyethylene resin porous membrane, an alcohol such as methanol, ethanol, or isopropyl alcohol, a ketone such as acetone or methyl ethyl ketone, water, or a solution of a solvent included in a feed solution or mixtures thereof may be passed through by bring into contact with the polyethylene resin porous membrane.

<Resin Composition for Forming Phase-Separated Structure>

The resin composition for forming a phase-separated structure, which is the object of filtering, includes a block copolymer and an organic solvent component.

<Block Copolymer>

A block copolymer is a polymeric material in which plurality of blocks (partial constitutional components in which the same kind of structural unit is repeatedly bonded) are bonded. As the blocks constituting the block copolymer, 2 kinds of blocks may be used, or 3 or more kinds of blocks may be used.

The plurality of blocks constituting the block copolymer are not particularly limited, as long as they are combinations capable of causing phase separation. However, it is preferable to use a combination of blocks which are mutually incompatible. Further, it is preferable to use a combination in which a phase of at least one block amongst the plurality of blocks constituting the block copolymer can be easily subjected to selective removal as compared to the phases of other blocks.

Further, it is preferable to use a combination in which a phase of at least one block amongst the plurality of blocks constituting the block copolymer can be easily subjected to selective removal as compared to the phases of other blocks. An example of a combination which can be selectively removed reliably include a block copolymer in which one or more blocks having an etching selectivity of more than 1 are bonded.

Examples of the block copolymer include a block copolymer in which a block of a structural unit having an aromatic group is bonded to a block of a structural unit derived from an (α-substituted) acrylate ester; a block copolymer in which a block of a structural unit having an aromatic group is bonded to a block of a structural unit derived from an (α-substituted) acrylic acid; a block copolymer in which a block of a structural unit having an aromatic group is bonded to a block of a structural unit derived from siloxane or a derivative thereof; a block copolymer in which a block of a structural unit derived from an alkyleneoxide is bonded to a block of a structural unit derived from an (α-substituted) acrylate ester; a block copolymer in which a block of a structural unit derived from an alkyleneoxide is bonded to a block of a structural unit derived from an (α-substituted) acrylic acid; a block copolymer in which a block of a structural unit containing a polyhedral oligomeric silsesquioxane structure is bonded to a block of a structural unit derived from an (α-substituted) acrylate ester; a block copolymer in which a block of a structural unit containing a silsesquioxane structure is bonded to a block of a structural unit derived from an (α-substituted) acrylic acid; and a block copolymer in which a block of a structural unit containing a silsesquioxane structure is bonded to a block of a structural unit derived from siloxane or a derivative thereof.

Examples of the structural unit having an aromatic group include structural units having a phenyl group, a naphthyl group or the like. Among these examples, a structural unit derived from styrene or a derivative thereof is preferable.

Examples of the styrene or derivative thereof include α-methylstyrene, 2-methylstyrene, 3-methylstyrene, 4-methylstyrene, 4-t-butylstyrene, 4-n-octylstyrene, 2,4,6-trimethylstyrene, 4-methoxystyrene, 4-t-butoxystyrene, 4-hydroxystyrene, 4-nitrostyrene, 3-nitrostyrene, 4-chlorostyrene, 4-fluorostyrene, 4-acetoxyvinylstyrene, 4-vinylbenzylchloride, 1-vinylnaphthalene, 4-vinylbiphenyl, 1-vinyl-2-pyrolidone, 9-vinylanthracene, and vinylpyridine.

An (α-substituted) acrylic acid refers to either or both acrylic acid and a compound in which the hydrogen atom bonded to the carbon atom on the α-position of acrylic acid has been substituted with a substituent. As an example of such a substituent, an alkyl group of 1 to 5 carbon atoms can be given.

Examples of (α-substituted) acrylic acid include acrylic acid and methacrylic acid.

An (α-substituted) acrylate ester refers to either or both acrylate ester and a compound in which the hydrogen atom bonded to the carbon atom on the α-position of acrylate ester has been substituted with a substituent. As an example of such a substituent, an alkyl group of 1 to 5 carbon atoms can be given. As an example of such a substituent, an alkyl group of 1 to 5 carbon atoms can be given.

Specific examples of the (α-substituted) acrylate ester include acrylate esters such as methyl acrylate, ethyl acrylate, propyl acrylate, n-butyl acrylate, t-butyl acrylate, cyclohexyl acrylate, octyl acrylate, nonyl acrylate, hydroxyethyl acrylate, hydroxypropyl acrylate, benzyl acrylate, anthracene acrylate, glycidyl acrylate, 3,4-epoxycyclohexylmethane acrylate, and propyltrimethoxysilane acrylate; and methacrylate esters such as methyl methacrylate, ethyl methacrylate, propyl methacrylate, n-butyl methacrylate, t-butyl methacrylate, cyclohexyl methacrylate, octyl methacrylate, nonyl methacrylate, hydroxyethyl methacrylate, hydroxypropyl methacrylate, benzyl methacrylate, anthracene methacrylate, glycidyl methacrylate, 3,4-epoxycyclohexylmethane methacrylate, and propyltrimethoxysilane methacrylate.

Among these, methyl acrylate, ethyl acrylate, t-butyl acrylate, methyl methacrylate, ethyl methacrylate, and t-butyl methacrylate are preferable.

Examples of siloxane and siloxane derivatives include dimethylsiloxane, diethylsiloxane, diphenylsiloxane, and methylphenylsiloxane.

Examples of the alkylene oxide include ethylene oxide, propylene oxide, isopropylene oxide and butylene oxide.

As the silsesquioxane structure-containing structural unit, polyhedral oligomeric silsesquioxane structure-containing structural unit is preferable. As a monomer which provides a polyhedral oligomeric silsesquioxane structure-containing structural unit, a compound having a polyhedral oligomeric silsesquioxane structure and a polymerizable group can be mentioned.

Among the above examples, as the block copolymer, a block copolymer containing a block of a structural unit having an aromatic group and a block of a structural unit derived from an (α-substituted) acrylic acid or an (α-substituted) acrylate ester is preferable.

In the case of obtaining a cylinder phase-separated structure oriented in a direction perpendicular to the surface of the substrate, the weight ratio of the structural unit having an aromatic group to the structural unit derived from an (α-substituted) acrylic acid or (α-substituted) acrylate ester is preferably in the range of 60:40 to 90:10, and more preferably 60:40 to 80:20.

In the case of obtaining a lamellar phase-separated structure oriented in a direction perpendicular to the surface of the substrate, the weight ratio of the structural unit having an aromatic group to the structural unit derived from an (α-substituted) acrylic acid or (α-substituted) acrylate ester is preferably in the range of 35:65 to 60:40, and more preferably 40:60 to 60:40.

Specific examples of such block copolymers include a block copolymer having a block of a structural unit derived from styrene and a block of a structural unit derived from acrylic acid; a block copolymer having a block of a structural unit derived from styrene and a block of a structural unit derived from methyl acrylate; a block copolymer having a block of a structural unit derived from styrene and a block of a structural unit derived from ethyl acrylate; a block copolymer having a block of a structural unit derived from styrene and a block of a structural unit derived from t-butyl acrylate; a block copolymer having a block of a structural unit derived from styrene and a block of a structural unit derived from methacrylic acid; a block copolymer having a block of a structural unit derived from styrene and a block of a structural unit derived from methyl methacrylate; a block copolymer having a block of a structural unit derived from styrene and a block of a structural unit derived from ethyl methacrylate; a block copolymer having a block of a structural unit derived from styrene and a block of a structural unit derived from t-butyl methacrylate; a block copolymer having a block of a structural unit containing a polyhedral oligomeric silsesquioxane (POSS) structure and a block of a structural unit derived from acrylic acid; and a block copolymer having a block of a structural unit containing a polyhedral oligomeric silsesquioxane (POSS) structure and a block of a structural unit derived from methyl acrylate.

In the present embodiment, the use of a block copolymer having a block of a structural unit derived from styrene (PS) and a block of a structural unit derived from methyl methacrylate (PMMA) is particularly preferable.

The number average molecular weight (Mn) (the polystyrene equivalent value determined by gel permeation chromatography (GPC)) of the block copolymer is preferably 20,000 to 200,000, more preferably 30,000 to 150,000, and still more preferably 50,000 to 90,000.

The dispersity (Mw/Mn) of the block copolymer is preferably 1.0 to 3.0, more preferably 1.0 to 1.5, and still more preferably 1.0 to 1.3. Here, Mw is the weight average molecular weight.

In the resin composition for forming a phase-separated structure, 1 kind of block copolymer may be used, or 2 or more kinds of block copolymers may be used in combination.

In the resin composition for forming a phase-separated structure, the amount of the block copolymer may be adjusted depending on the thickness of the layer containing the block copolymer to be formed.

<Ion Liquid>

In the present embodiment, the resin composition for forming a phase-separated structure may include an ion liquid. The ion liquid contains a compound (IL) having a cation moiety and an anion moiety.

An ion liquid refers to a salt which is present in the form of a liquid. An ion liquid is constituted of a cation moiety and an anion moiety. The electrostatic interaction between the cation moiety and the anion moiety is week, and the salt is unlikely to be crystallized. The ion liquid has a boiling point of 100° C. or lower, and has the following characteristics 1) to 5).

Characteristic 1) The vapor pressure is extremely low. Characteristic 2) Non-flammable over a wide temperature range. Characteristic 3) Maintains a liquid state over a wide temperature range Characteristic 4) The density can be largely changed. Characteristic 5) The polarity can be controlled.

In the present embodiment, the ion liquid may be non-polymeric.

The weight average molecular weight (Mw) of the ion liquid is preferably 1,000 or less, more preferably 750 or less, and still more preferably 500 or less.

«Compound (IL)»

The compound (IL) is a compound having a cation moiety and an anion moiety.

Cation Moiety of Compound (IL)

The cation moiety of the compound (IL) is not particularly limited. However, in terms of improvement in the phase-separation performance, the cation moiety preferably has a dipole moment of 3 debye or more, more preferably 3.2 to 15 debye, and still more preferably 3.4 to 12 debye.

The “dipole moment of the cation moiety” is a parameter quantitatively indicating the polarity (deviation of charge) of the cation moiety. 1 debye is defined as 1×10⁻¹⁸esu·cm. In the present specification, the dipole moment of the cation moiety refers to a simulation value by CAChe. For example, the dipole moment of the cation moiety can be determined by optimization of the structure by CAChe Work System Pro Version 6.1.12.33, using MM geometry (MM2) and PM3 geometry.

Preferable examples of cation moiety having a dipole moment of 3 debye or more include an imidazolium ion, a pyrrolidinium ion, a piperidinium ion and an ammonium ion.

That is, preferable examples of the compound (IL) include an imidazolium salt, a pyrrolidinium salt, a piperidinium salt and an ammonium salt. Among these salts, in terms of improving the phase-separation performance, the cation moiety preferably has a substituent. Among these, a cation containing an alkyl group of 2 or more carbon atoms optionally having a substituent, or a cation containing a polar group. The alkyl group of 2 or more carbon atoms contained in the cation preferably has 2 to 12 carbon atoms, more preferably 2 to 6 carbon atoms. The alkyl group may be a linear alkyl group or a branched alkyl group, but is preferably a linear alkyl group. Examples of the substituent for the alkyl group of 2 or more carbon atoms include a hydroxy group, a vinyl group and an allyl group. The alkyl group of 2 or more carbon atoms preferably has no substituent. Examples of the polar group contained in the cation include a carboxy group, a hydroxy group, an amino group and a sulfo group.

More preferable examples of the cation moiety of the compound (IL) include a pyrrolidinium ion. Among pyrrolidinium ions, a pyrrolidinium ion containing an alkyl group of 2 or more carbon atoms which may have a substituent is preferable.

Anion Moiety of Compound (IL)

The anion moiety of the compound (IL) is not particularly limited, and examples thereof include anions represented by any one of general formulae (a1) to (a5) shown below.

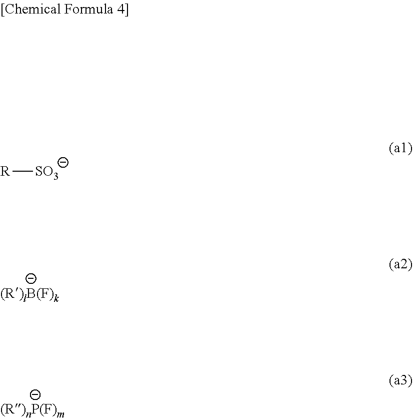

In formula (a1), R represents an aromatic hydrocarbon group which may have a substituent, an aliphatic cyclic group which may have a substituent, or a chain hydrocarbon group which may have a substituent. In formula (a2), R′ represents an alkyl group of 1 to 5 carbon atoms optionally substituted with a fluorine atom. k represents an integer of 1 to 4, and 1 represents an integer of 0 to 3, provided that k+1=4. in formula (a3), R″ represents an alkyl group of 1 to 5 carbon atoms optionally substituted with a fluorine atom; m represents an integer of 1 to 6, and n represents an integer of 0 to 5, provided that m+n=6.

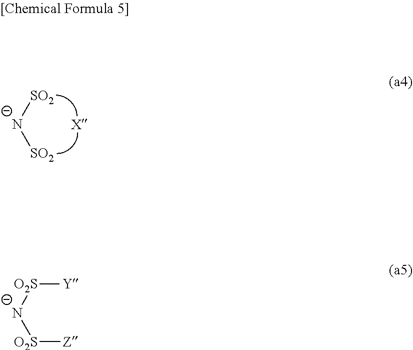

In formula (a4), X″ represents an alkylene group of 2 to 6 carbon atoms in which at least one hydrogen atom has been substituted with a fluorine atom; in formula (a5), Y″ and Z″ each independently represents an alkyl group of 1 to 10 carbon atoms in which at least one hydrogen atom has been substituted with a fluorine atom;

In general formula (a1), R represents an aromatic hydrocarbon group which may have a substituent, an aliphatic cyclic group which may have a substituent, pr a chain hydrocarbon group which may have a substituent.

In general formula (a1), in the case where R is an aromatic hydrocarbon group which may have a substituent, examples of the aromatic ring contained in the aromatic hydrocarbon group include aromatic hydrocarbon rings, such as benzene, biphenyl, fluorene, naphthalene, anthracene and phenanthrene; and aromatic hetero rings in which part of the carbon atoms constituting the aforementioned aromatic hydrocarbon rings has been substituted with a hetero atom. Examples of the hetero atom within the aromatic hetero rings include an oxygen atom, a sulfur atom and a nitrogen atom.

Specific examples of the aromatic hydrocarbon group include a group in which 1 hydrogen atom has been removed from the aforementioned aromatic hydrocarbon ring (aryl group); and a group in which 1 hydrogen atom of the aforementioned aryl group has been substituted with an alkylene group (an arylalkyl group such as a benzyl group, a phenethyl group, a 1-naphthylmethyl group, a 2-naphthylmethyl group, a 1-naphthylethyl group or a 2-naphthylethyl group). The alkylene group (alkyl chain within the arylalkyl group) preferably has 1 to 4 carbon atom, more preferably 1 or 2, and most preferably 1.

As the aromatic hydrocarbon group for R, a phenyl group or a naphthyl group is preferable, and a phenyl group is more preferable.

In general formula (al), in the case where R represents an aliphatic cyclic group which may have a substituent, the cyclic group may be polycyclic or monocyclic. As the monocyclic aliphatic hydrocarbon group, a group in which one hydrogen atoms have been removed from a monocycloalkane is preferable. The monocycloalkane preferably has 3 to 8 carbon atoms, and specific examples thereof include cyclopentane, cyclohexane and cyclooctane. As the polycyclic aliphatic cyclic group, a group in which one hydrogen atoms have been removed from a polycycloalkane is preferable, and the polycyclic group preferably has 7 to 12 carbon atoms. Examples of the polycycloalkane include adamantane, norbornane, isobornane, tricyclodecane and tetracyclododecane.

Among these examples, as the aliphatic cyclic group, groups in which one or more hydrogen atoms have been removed from a polycycloalkane such as adamantane, norbornane, isobornane, tricyclodecane or tetracyclododecane are more preferable.

In general formula (a1), as the chain hydrocarbon group for R, a chain alkyl group is preferable. The chain-like alkyl group preferably has 1 to 10 carbon atoms, and specific examples thereof include a linear alkyl group such as a methyl group, an ethyl group, a propyl group, a butyl group, a pentyl group, a hexyl group, a heptyl group, an octyl group, a nonyl or a decyl group, and a branched alkyl group such as a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group or a 4-methylpentyl group. The chain-like alkyl group preferably has 1 to 6 carbon atoms, and more preferably 1 to 3 carbon atoms. Further, a linear alkyl group is preferable.

In general formula (a1), examples of the substituent for the aromatic hydrocarbon group, the aliphatic cyclic group or the chain hydrocarbon group for R include a hydroxy group, an alkyl group, a fluorine atom or a fluorinated alkyl group.

In general formula (a1), as R, a methyl group, a trifluoromethyl group or a p-tolyl group is preferable.

In general formula (a2), R′ represents an alkyl group of 1 to 5 carbon atoms optionally substituted with a fluorine atom.

k represents an integer of 1 to 4, preferably an integer of 3 to 4, and most preferably 4.

1 represents an integer of 0 to 3, preferably 0 to 2, most preferably 0. When 1 is 2 or more, the plurality of R′ may be the same or different from each other, but are preferably the same.

In general formula (a3), R″ represents an alkyl group of 1 to 5 carbon atoms optionally substituted with a fluorine atom;

m represents an integer of 1 to 6, preferably an integer of 3 to 6, and most preferably 6.

n represents an integer of 0 to 5, preferably 0 to 3, most preferably 0. When n is 2 or more, the plurality of R″ may be the same or different from each other, but are preferably the same.

In formula (a4), X″ represents an alkylene group of 2 to 6 carbon atoms in which at least one hydrogen atom has been substituted with a fluorine atom. The alkylene group may be linear or branched, and has 2 to 6 carbon atoms, preferably 3 to 5 carbon atoms, and most preferably 3 carbon atoms.

In formula (a5), Y″ and Z″ each independently represents an alkyl group of 1 to 10 carbon atoms in which at least one hydrogen atom has been substituted with a fluorine atom. The alkyl group may be linear or branched, and has 1 to 10 carbon atoms, preferably 1 to 7 carbon atoms, and most preferably 1 to 3 carbon atoms.

The smaller the number of carbon atoms of the alkylene group for X″ or those of the alkyl group for Y″ and Z″ within the above-mentioned range of the number of carbon atoms, the more the solubility in an organic solvent component is improved.

In the alkylene group for X″ and the alkyl group for Y″ and Z″, it is preferable that the number of hydrogen atoms substituted with fluorine atoms is as large as possible because the acid strength increases. The amount of fluorine atoms within the alkylene group or alkyl group, i.e., fluorination ratio, is preferably from 70 to 100%, more preferably from 90 to 100%, and it is particularly desirable that the alkylene group or alkyl group be a perfluoroalkylene or perfluoroalkyl group in which all hydrogen atoms are substituted with fluorine atoms.

As the anion moiety of the compound (IL), among the anion moieties represented by the aforementioned general formulae (a1) to (a5), an anion moiety represented by general formula (a1) or (a5) is preferable.

Preferable combinations of the anion moiety and the cation moiety of the compound (IL) include a combination of a cation moiety consisting of a pyrrolidinium ion and an anion moiety represented by the aforementioned general formula (a1) or (a5).

Specific examples of the compound (IL) are shown below, but the compound (IL) is by no means limited by these examples.

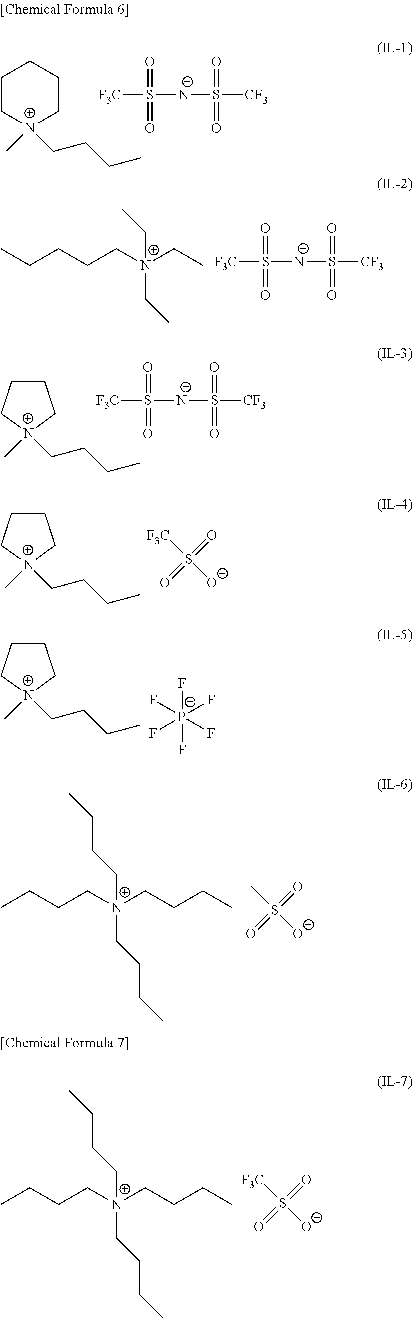

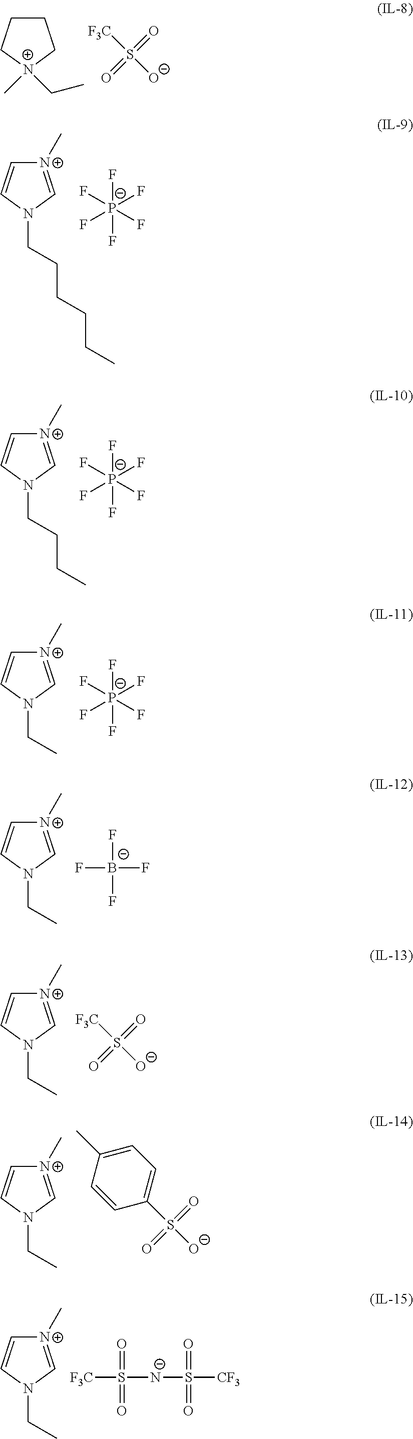

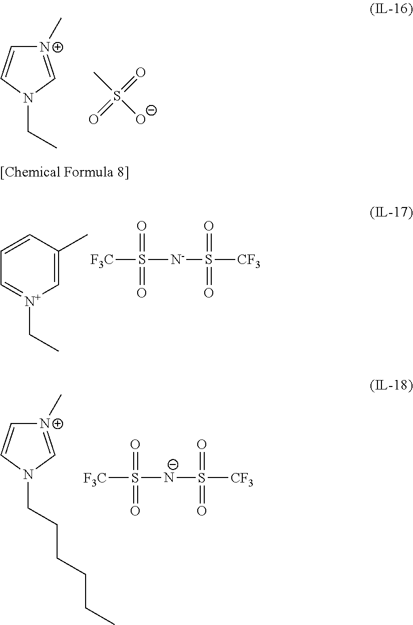

In the present embodiment, in the case where the resin composition for forming a phase-separated structure includes an ion liquid, as the compound (IL), 1 kind of compound may be used, or 2 or more kinds of compounds may be used in combination.

In the resin composition for forming a phase-separated structure, the amount of the compound (IL) relative to 100 parts by weight of the block copolymer is preferably 0.05 to 50 parts by weight, more preferably 0.1 to 40 parts by weight, and still more preferably 0.5 to 30 parts by weight.

When the amount of the compound (IL) is within the above preferable range, the phase-separation performance may be further improved.

(Organic Solvent Component)

In the present embodiment, the organic solvent component contained in the resin composition for forming a phase-separated structure (hereafter, sometimes referred to simply as “organic solvent”) may be any organic solvent which can dissolve the respective components to give a uniform solution, and one or more kinds of any organic solvent can be appropriately selected from those which have been conventionally known as solvents for a film composition containing a resin as a main component. Examples thereof include halogenated hydrocarbons such as methylchloride, dichloromethane, chloroform, ethyl chloride, dichloroethane, n-propylchloride, n-butylchloride and chlorobenzene; lactones such as γ-butyrolactone; ketones such as acetone, methyl ethyl ketone, cyclohexanone, methyl-n-pentyl ketone, methyl isopentyl ketone, and 2-heptanone (methylamyl ketone); polyhydric alcohols, such as ethylene glycol, diethylene glycol, propylene glycol and dipropylene glycol; compounds having an ester bond, such as ethylene glycol monoacetate, diethylene glycol monoacetate, propylene glycol monoacetate, and dipropylene glycol monoacetate; polyhydric alcohol derivatives including compounds having an ether bond, such as a monoalkylether (e.g., monomethylether, monoethylether, monopropylether or monobutylether) or monophenylether of any of these polyhydric alcohols or compounds having an ester bond (among these, propylene glycol monomethyl ether acetate (PGMEA) and propylene glycol monomethyl ether (PGME) are preferable); cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate; and aromatic organic solvents such as anisole, ethylbenzylether, cresylmethylether, diphenylether, dibenzylether, phenetole, butylphenylether, ethylbenzene, diethylbenzene, pentylbenzene, isopropylbenzene, toluene, xylene, cymene and mesitylene.

These solvents can be used individually, or in combination as a mixed solvent. Among these examples, chloroform, 2-heptanone, propylene glycol monomethyl ether acetate (PGMEA) , propylene glycol monomethyl ether (PGME), cyclohexanone and EL is preferable, and PEGMEA is more preferable.

Further, among the mixed solvents, a mixed solvent obtained by mixing PGMEA with a polar solvent is preferable. The mixing ratio (weight ratio) of the mixed solvent can be appropriately determined, taking into consideration the compatibility of the PGMEA with the polar solvent, but is preferably in the range of 1:9 to 9:1, more preferably from 2:8 to 8:2. For example, when EL is mixed as the polar solvent, the PGMEA:EL weight ratio is preferably from 1:9 to 9:1, and more preferably from 2:8 to 8:2. Alternatively, when PGME is mixed as the polar solvent, the PGMEA:PGME weight ratio is preferably from 1:9 to 9:1, more preferably from 2:8 to 8:2, and still more preferably 3:7 to 7:3. Alternatively, when PGME and cyclohexanone is mixed as the polar solvent, the PGMEA:(PGME+cyclohexanone) weight ratio is preferably from 1:9 to 9:1, more preferably from 2:8 to 8:2, and still more preferably 3:7 to 7:3.

Further, as the organic solvent for the resin composition for forming a phase-separated structure, a mixed solvent of γ-butyrolactone with PGMEA, EL or the aforementioned mixed solvent of PGMEA with a polar solvent, is also preferable. The mixing ratio (former:latter) of such a mixed solvent is preferably from 70:30 to 95:5.

The amount of the organic solvent in the resin composition for forming a phase-separated structure is not particularly limited, and is adjusted appropriately to a concentration that enables application of a coating solution depending on the thickness of the coating film. In general, the organic solvent is used in an amount that yields a solid content for the block copolymer that is within a range from 0.2 to 70% by weight, and preferably from 0.2 to 50% by weight.

In the method of producing purified product of resin composition for forming a phase-separated structure according to the present embodiment, in step (i), the object of filtering (resin composition for forming a phase-separated structure) is subjected to filtration using filter having a porous structure in which adjacent spherical cells are mutually communicating, the filter being provided with a porous membrane containing at least one resin skeleton selected from the group consisting of polyimide and polyamideimide. Thus, foreign matters such as organic materials and metallic impurities are removed from the object of filtering better than ever. In particular, by the polyimide resin porous membrane being used, high polar components and polymers which was difficult to be removed in the related art is sufficiently removed from the object of filtering, and among these, high polar polymers are specifically removed. In addition, in step (i), metal components which are impurities may be satisfactorily removed from the object of filtering. Thus, as described above, according to the production method, various foreign matters may be efficiently removed, and a purified product of resin composition for forming a phase-separated structure may be obtained with high purity.

The filter in the present aspect is not limited to a filter provided with a porous membrane in which a communicating pore 5 through which the spherical cell 1a and the spherical cells lb adjacent as shown in FIG. 1 are communicating is formed, and in addition to the communicating pore 5 through which the spherical cell 1a and the spherical cells lb are communicating, the filter may be provided with a porous membrane in which other forms of cells or communicating pores are formed.

As other forms of cells (hereinafter, this is referred as “other cells”), cells having a different shape or pore diameter can be given, and examples thereof include ellipse shape cells, polyhedral cells, and spherical cells having a different pore diameter. As the “other forms of communicating pores” described above, for example, communicating pores through which spherical cells and other cells are communicating can be given.

The shape or pore diameter of the other cells may be suitably determined depending on the type of impurities which are removal targets. The communicating pores through which spherical cells and other cells are communicating are formed by selecting the material of the above-described fine particles, or by controlling the shape of the fine particles.

In addition to the communicating pores through which adjacent spherical cells are mutually communicating, according to the filter provided with a porous membrane in which other forms of cells or communicating pores are formed, various types of foreign matters are more efficiently removed from an object of filtering.

In addition, the filter having the polyimide resin porous membrane, used in the filtration step, replaces the filter cartridge or the like for removing the fine particle impurities installed in the related art in the supply line or point of use (POU) of various resin composition for forming a phase-separated structure in the semiconductor production process, an can be used in combination therewith. Therefore, by the exactly same apparatus and operation in the related art, various foreign matters can be efficiently removed from the object for filtering, and a purified product of a resin composition for forming a phase-separated structure with high purity can be produced.

(Method of Producing Structure Containing Phase-Separated Structure)

A second aspect of the present invention is a method of producing a structure containing phase-separated structure, the method including: obtaining a purified product of a resin composition for forming a phase-separated structure by the method according to the first aspect (hereafter, referred to as “step (i′)”); using the purified product of the resin composition to form a BCP layer containing the block copolymer on a substrate (hereafter, referred to as “step (i)”); and phase-separating the BCP layer to obtain a structure containing a phase-separated structure (hereafter, referred to as “step (ii)”).

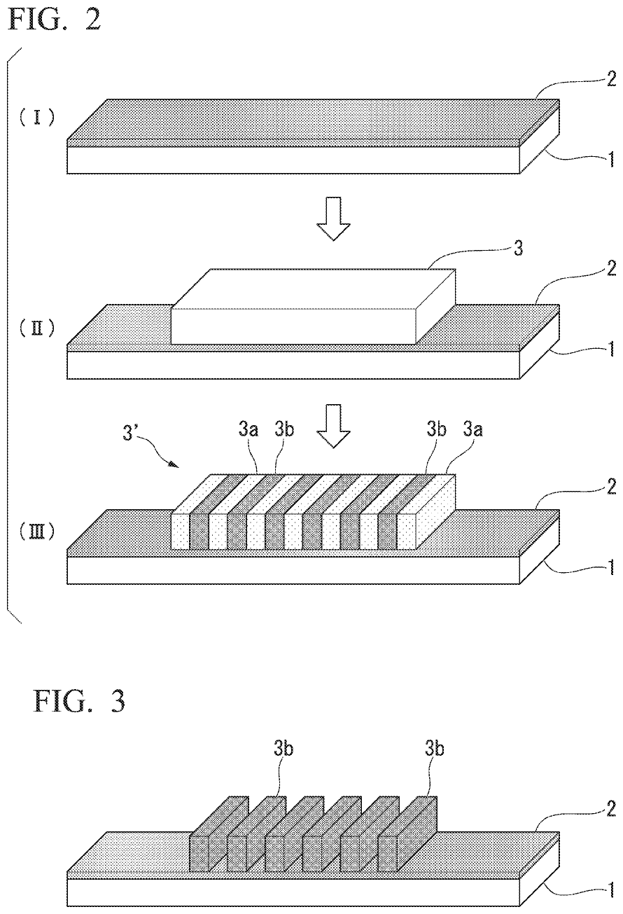

Hereinafter, the method of producing a structure containing a phase-separated structure will be specifically described with reference to FIG. 2. However, the present invention is not limited to these embodiments.

FIG. 2 shows an example of one embodiment of the method of forming a structure containing a phase-separated structure. In the present embodiment, a purified product of a resin composition for forming a phase-separated structure is obtained in advance by the method of producing purified product of resin composition for forming a phase-separated structure according to the first aspect (step (i′)).

Firstly, a brush composition is applied to a substrate 1, so as to form a brush layer 2 (FIG. 2 (I)).

Then, to the brush layer 2, a purified product of a resin composition for forming a phase-separated structure is applied, so as to form a BCP layer 3 (FIG. 2(II); step (i)).

Next, heating is conducted to perform an annealing treatment, so as to phase-separate the BCP layer 3 into a phase 3a and a phase 3b. (FIG. 2 (III); step (ii)).

According to the production method of the present embodiment, that is, the production method including the steps (i′), (i) and (ii), a structure 3′ containing a phase-separated structure is formed on the substrate 1 having the brush layer 2 formed thereon.

[Step (i′)]

In step (i′), a purified product of a resin composition for forming a phase-separated structure is obtained by the same method as in the first aspect.

[Step (i)]

In step (i), the purified product of the resin composition for forming a phase-separated structure is applied to the substrate 1, so as to form a BCP layer 3.

There are no particular limitations on the type of a substrate, provided that the purified product of the resin composition for forming a phase-separated structure can be coated on the surface of the substrate.

Examples of the substrate include a substrate constituted of an inorganic substance such as a metal (e.g., silicon, copper, chromium, iron or aluminum), glass, titanium oxide, silica or mica; and a substrate constituted of an organic substance such as an acrylic plate, polystyrene, cellulose, cellulose acetate or phenol resin.

The size and the shape of the substrate is not particularly limited. The substrate does not necessarily need to have a smooth surface, and a substrate made of various materials and having various shapes can be appropriately selected for use. For example, a multitude of shapes can be used, such as a substrate having a curved surface, a plate having an uneven surface, and a thin sheet.

On the surface of the substrate, an inorganic and/or organic film may be provided. As the inorganic film, an inorganic antireflection film (inorganic BARC) can be used. As the organic film, an organic antireflection film (organic BARC) can be used.

Before forming a BCP layer 3 on the substrate 1, the surface of the substrate 1 may be cleaned. By cleaning the surface of the substrate, application of the purified product of the resin composition for forming a phase-separated structure or the brush composition to the substrate 1 may be satisfactorily performed.

As the cleaning treatment, a conventional method may be used, and examples thereof include an oxygen plasma treatment, a hydrogen plasma treatment, an ozone oxidation treatment, an acid alkali treatment, and a chemical modification treatment. For example, the substrate is immersed in an acidic solution such as a sulfuric acid/hydrogen peroxide aqueous solution, followed by washing with water and drying. Thereafter, a BCP layer 3 or a brush layer 2 is formed on the surface of the substrate.

Before forming a BCP layer 3 on the substrate 1, the surface of the substrate 1 may be subjected to a neutralization treatment.

A “neutralization treatment” is a treatment in which a surface of a substrate is modified to provide affinity for all polymers which constitute the purified product of the resin composition for forming a phase-separated structure. By the neutralization treatment, it becomes possible to prevent only phases of specific polymers to come into contact with the surface of the substrate by phase separation. For example, prior to forming a BCP layer 3, it is preferable to form a brush layer 2 on a surface of the substrate 1, depending on the kind of the purified product of the resin composition for forming a phase-separated structure to be used. As a result, by phase-separation of the BCP layer 3, a cylinder structure or lamellar structure oriented in a direction perpendicular to the surface of the substrate 1 can be reliably formed.

Specifically, on the surface of the substrate 1, a brush layer 2 is formed using a brush composition having affinity for all polymers constituting the purified product of the resin composition for forming a phase-separated structure.

The brush composition can be appropriately selected from conventional resin compositions used for forming a thin film, depending on the kind of polymers constituting the purified product of the resin composition for forming a phase-separated structure.

Examples of the brush composition include a composition containing a resin which has all structural units of the polymers constituting the purified product of the resin composition for forming a phase-separated structure, and a composition containing a resin which has all structural units having high affinity for the polymers constituting the purified product of the resin composition for forming a phase-separated structure.

For example, when a block copolymer having a block of a structural unit derived from styrene (PS) and a block of a structural unit derived from methyl methacrylate (PMMA) (PS-PMMA block copolymer) is used, as the brush composition, it is preferable to use a resin composition containing both PS and PMMA, or a compound or a composition containing both a portion having a high affinity for an aromatic ring and a portion having a high affinity for a functional group with high polarity as blocks.

Examples of the resin composition containing both PS and PMMA as blocks include a random copolymer of PS and PMMA, and an alternating polymer of PS and PMMA (a copolymer in which the respective monomers are alternately copolymerized).

Examples of the composition containing both a portion having a high affinity for PS and a portion having a high affinity for PMMA include a resin composition obtained by polymerizing at least a monomer having an aromatic ring and a monomer having a substituent with high polarity. Examples of the monomer having an aromatic ring include a monomer having a group in which one hydrogen atom has been removed from the ring of an aromatic hydrocarbon, such as a phenyl group, a biphenyl group, a fluorenyl group, a naphthyl group, an anthryl group or a phenanthryl group, or a monomer having a hetero aryl group such as the aforementioned group in which part of the carbon atoms constituting the ring of the group has been substituted with a hetero atom such as an oxygen atom, a sulfur atom or a nitrogen atom. Examples of the monomer having a substituent with high polarity include a monomer having a trimethoxysilyl group, a trichlorosilyl group, a carboxy group, a hydroxy group, a cyano group or a hydroxyalkyl group in which part of the hydrogen atoms of the alkyl group has been substituted with fluorine atoms.

Examples of the compound containing both a portion having a high affinity for PS and a portion having a high affinity for PMMA include a compound having both an aryl group such as a phenethyltrichlorosilane and a substituent with high polarity, and a compound having both an alkyl group and a substituent with high polarity, such as an alkylsilane compound.

Further, as the brush composition, for example, a heat-polymerizable resin composition, or a photosensitive resin composition such as a positive resist composition or a negative resist composition can also be mentioned.

The brush layer may be formed by a conventional method. The method of applying the brush composition to the substrate 1 to form a brush layer 2 is not particularly limited, and the brush layer 2 can be formed by a conventional method.

For example, the brush composition can be applied to the substrate 1 by a conventional method using a spinner or the like to form a coating film on the substrate 1, followed by drying, thereby forming a brush layer 2. The drying method of the coating film is not particularly limited, provided it can volatilize the solvent contained in the brush composition, and a baking method and the like are exemplified. The baking temperature is preferably 80° C. to 300° C., more preferably 180° C. to 270° C., and still more preferably 220° C. to 250° C. The baking time is preferably 30 seconds to 500 seconds, and more preferably 60 seconds to 400 seconds.

The thickness of the brush layer 2 after drying of the coating film is preferably about 10 to 100 nm, and more preferably about 40 to 90 nm.

Subsequently, on the brush layer 2, a BCP layer 3 is formed using the purified product of the resin composition for forming a phase-separated structure.

The method of forming the BCP layer 3 on the brush layer 2 is not particularly limited, and examples thereof include a method in which the purified product of the resin composition for forming a phase-separated structure is applied to the brush layer 2 by a conventional method using spin-coating or a spinner, followed by drying.

The drying method of the coating film of the purified product of the resin composition for forming a phase-separated structure is not particularly limited, provided it can volatilize the organic solvent component included in the purified product of the resin composition for forming a phase-separated structure. Examples of the drying method include a shaking method and a baking method.

The BCP layer 3 may have a thickness satisfactory for phase-separation to occur. In consideration of the kind of the substrate 1, the structure period size of the phase-separated structure to be formed, and the uniformity of the nanostructure, the thickness is preferably 10 to 100 nm, and more preferably 30 to 80 nm.

For example, in the case where the substrate 1 is an Si substrate or an SiO₂, the thickness of the BCP layer 3 is preferably 20 to 100 nm, and more preferably 30 to 80 nm.

In the case where the substrate 1 is a Cu substrate, the thickness of the BCP layer 3 is preferably 10 to 100 nm, and more preferably 30 to 80 nm.

[Step (ii)]

In step (ii), the BCP layer 3 formed on the substrate 1 is phase-separated. By heating the substrate 1 after step (i) to conduct the anneal treatment, the block copolymer is selectively removed, such that a phase-separated structure in which at least part of the surface of the substrate 1 is exposed is formed. That is, on the substrate 1, a structure 3′ containing a phase-separated structure in which phase 3a and phase 3b are phase separated is produced.

The temperature condition in the anneal treatment is preferably 210° C. or higher, more preferably 220° C. or higher, still more preferably 230° C. or higher, and most preferably 240° C. or higher. The upper limit of the temperature condition in the anneal treatment is not particularly limited, but is preferably lower than the heat decomposition temperature of the block copolymer. For example, the temperature condition of the anneal treatment is preferably 400° C. or lower, more preferably 350° C. or lower, and still more preferably 300° C. or lower. The range of the temperature conditions in the anneal treatment may be, for example, 210 to 400° C., 220 to 350° C., 230 to 300° C., or 240 to 300° C.

In the anneal treatment, the heating time is preferably 1 minute or more, more preferably 5 minutes or more, still more preferably 10 minutes or more, and most preferably 15 minutes or more. By extending the heating time, in the case where the purified product of the resin composition for forming a phase-separated structure contains a compound (IL), the amount of the compound (IL) remaining in the BCP layer may be reduced. The upper limit of the heating time is not particularly limited. In view of controlling the process time, the heating time is preferably 240 minutes or less, and more preferably 180 minutes or less. The range of the heating time in the anneal treatment may be, for example, 1 to 240 minutes, 5 to 240 minutes, 10 to 240 minutes, 15 to 240 minutes, or 15 to 180 minutes.

Further, the anneal treatment is preferably conducted in a low reactive gas such as nitrogen.

In in the case where the purified product of the resin composition for forming a phase-separated structure contains a compound (IL), by conducting an anneal treatment, the compound (IL) is volatilized and removed from the BCP layer. As a result, in the BCP layer after the anneal treatment (i.e., structure 3′ in FIG. 1 (III)), the film thickness is reduced as compared to the BCP layer prior to the anneal treatment, depending on the amount of the compound (IL) volatilized and removed. The ratio (ta/tb) of the thickness (ta (nm)) of the BCP layer after the anneal treatment to the thickness (tb (nm)) of the

BCP layer prior to the anneal treatment is preferably, for example, 0.90 or less. The value of (ta/tb) is more preferably 0.85 or less, still more preferably 0.80 or less, and most preferably 0.75 or less. As the value of (ta/tb) becomes smaller, the amount of the compound (IL) remaining in the BCP layer reduces. As a result, a structure having a good shape with reduced generation of roughness can be obtained. The lower limit of the value of (ta/tb) is not particularly limited, and may be, for example, 0.50 or more.

In the method of forming a structure containing a phase-separated structure according to the present embodiment described above, since a purified product of the resin composition for forming a phase-separated structure obtained by the method according to the first aspect is used, generation of defects can be suppressed, and it becomes possible to form a structure containing a phase-separated structure (phase-separated pattern) having a good shape can be formed with reduced deficiencies such as generation of scums and microbridges.

The defect count of the phase-separated pattern can be obtained by measuring the total number of defects in the substrate (total number of defects, unit: number) using a surface defect observation device (for example, a device manufactured by KLA Tencor Co., Ltd.).

(Purified Product of Resin Composition for Forming a Phase-Separated Structure)

The purified product of resin composition for forming a phase-separated structure according to the third aspect of the present invention includes a block copolymer and an organic solvent component. In the purified product of resin composition for forming a phase-separated structure, the number of objects having a size of 0.11μm or more is less than 5/cm³, as counted by a light scattering type liquid-borne particle counter.

The purified product of resin composition for forming a phase-separated structure according to the present aspect can be obtained by the production method according to the first aspect. The purified product of resin composition for forming a phase-separated structure obtained by the production method according to the first aspect has been filtered by being allowed to pass thorough a filter provided with a polyimide resin porous membrane, and has foreign matters removed therefrom. Therefore, in the purified product of resin composition for forming a phase-separated structure according to the present aspect, the number of objects having a size of 0.11μm or more is less than 5/cm³, as counted by a light scattering type liquid-borne particle counter, and a resin composition product for forming a phase-separated structure having a very small number of foreign matters can be realized.

In the purified product of resin composition for forming a phase-separated structure according to the present aspect, the number of objects having a size of 0.11 μm or more is preferably 3/cm³ or less, more preferably 2/cm³ or less, still more preferably 1.8/cm³ or less, and still more preferably 1/cm³ or less.

Since the purified product of resin composition for forming a phase-separated structure of the present aspect has a very small number of foreign matters, a phase-separated pattern having a small number of defects may be formed.

As the light scattering type liquid-borne particle counter, for example, KS-41B manufactured by RION Co., Ltd.

(Method of Producing Structure Containing Phase-Separated Structure)

The method of producing structure containing phase-separated structure according to the fourth aspect of the present invention includes: using the purified product of a resin composition for forming a phase-separated structure according to the third aspect to form a BCP layer containing the block copolymer on a substrate; and phase-separating the BCP layer to obtain a structure containing a phase-separated structure.

The method of producing structure containing phase-separated structure according to the present aspect can be performed in the same manner as in the method of producing structure containing phase-separated structure according to the second aspect.

### EXAMPLES

As follows is a description of examples of the present invention, although the scope of the present invention is by no way limited by these examples.

(Preparation of Resin Composition for Forming Phase-Separated Structure)

100 Parts by weight of a block copolymer constituted of polystyrene (PS block) and poly(methyl methacrylate) (PMMA block) [Mn: PS30000, PMMA: 30000, total: 60000; PS/PMMA compositional ratio (weight ratio): 50/50; dispersity: 1.02] was dissolved in 7,660 parts by weight of propyleneglycol monomethylether acetate (PGMEA), so as to prepare a resin composition (P)-1 for forming a phase-separated structure.

(Production of Purified Product of Resin Composition for Forming a Phase-Separated Structure (1))

The resin composition (P)-1 for forming a phase-separated structure was subjected to filtration using the filter and filtering conditions shown in Table 2, so as to produce a purified product of a resin composition for forming a phase-separated structure. The filters were arranged in the order of the first filter, the second filter, and the third filter from upstream to downstream. In each example, circulation filtration was performed in which the resin composition (P)-1 for forming a phase-separated structure was passed through each filter 10 times.

The types of filters (1), (2) and (3) are shown in Table 1. The porous membrane in the filter (1) was obtained according to the production method described in Japanese Unexamined Patent Application, First Publication No. 2017-68262. In the filters (1) and (2), the average pore diameter of the communicating pores as measured by the BET method was about 8 nm and about 18 nm, respectively.

TABLE 1

| Filter | |
|---|---|
| (1) | A 10-inch filter having a polyimide resin structure and a porous |
| | membrane having a porous structure in which communicating |
| | pores are formed in which adjacent spherical cells communicate |
| | with each other. The average diameter of sherical cells: 300 nm. |
| (2) | A 10-inch filter equipped with a polyamide (nylon) porous |
| | membrane. |
| (3) | 10 inch filter euipped with a polyethylene porous membrane. |
| | Pore size 1 nm, manufactured by Entegris. |

TABLE 2

| | | | | Filtering conditions | |
|---|---|---|---|---|---|
| | Filter | | | Filtering | Filtering |
| | 1st | 2nd | 3rd | pressure | temperature |
| | filter | Filter | filter | (MPa) | (° C.) |
| Example 1 | (1) | — | — | 0.2 | 23 |
| Example 2 | (1) | (2) | — | 0.2 | 23 |
| Example 3 | (1) | (3) | — | 0.2 | 23 |
| Example 4 | (3) | (1) | — | 0.2 | 23 |
| Example 5 | (1) | (2) | (3) | 0.2 | 23 |
| Comparative | (2) | — | — | 0.2 | 23 |
| Example 1 | | | | | |
| Comparative | (3) | — | — | 0.2 | 23 |
| Example 2 | | | | | |
| Comparative | (2) | (3) | — | 0.2 | 23 |
| Example 3 | | | | | |

«Evaluation of Purified Product of Resin Composition for Forming a Phase-Separated Structure (1)»

Regarding the purified product of the resin composition for forming a phase-separated structure of each example, a light scattering type liquid particle counter [manufactured by Rion Co., Ltd., model number: KS-41B, light source: diode pumped solid state laser (wavelength 532 nm, rated output 500 mW), rated flow rate: 5 mL/min] based on a dynamic light scattering method, was used to count the number of objects having a size of 0.11 μm or more. The counting was performed 3 times, and the average value was used as the measured value. The light scattering type liquid particle counter was used after calibrating with a PSL (Polystyrene Latex) standard particle solution. The results are indicated under “Number of particles (number/cm³)” in Table 3.

TABLE 3

| | Number of particles |
|---|---|
| | (Number/cm³) |
| Example 1 | 2.7 |
| Example 2 | 0.5 |
| Example 3 | 1.6 |
| Example 4 | 1.6 |
| Example 5 | 0.3 |
| Comparative | 24.3 |
| Example 1 | |
| Comparative | 32.4 |
| Example 2 | |
| Comparative | 21.6 |
| Example 3 | |

As seen from the results shown in Table 3, it was confirmed that the number of particles were reduced in the purified product of the resin composition for forming a phase-separated structure of Examples 1 to 5, as compared to the purified product of the resin composition for forming a phase-separated structure of Comparative Examples 1 to 3.

(Preparation of Resin Composition for Forming Phase-Separated Structure (2))

100 Parts by weight of a block copolymer constituted of polystyrene (PS block) and poly(methyl methacrylate) (PMMA block) [Mn: PS30000, PMMA: 30000, total: 60000; PS/PMMA compositional ratio (weight ratio): 50/50; dispersity: 1.02] and 2 parts by weight of compound (IL-1) represented by chemical formula (IL-1) shown below were dissolved in 7,660 parts by weight of propyleneglycol monomethylether acetate (PGMEA), so as to prepare a resin composition (P)-2 for forming a phase-separated structure.

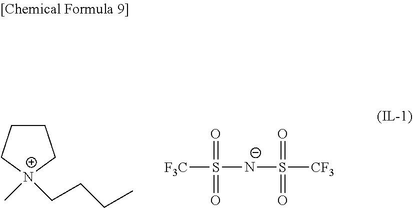

(Production of Purified Product of Resin Composition for Forming a Phase-Separated Structure (2))

The resin composition (P)-2 for forming a phase-separated structure was subjected to filtration using the filter and filtering conditions shown in Table 4, so as to produce a purified product of a resin composition for forming a phase-separated structure.

The filters were arranged in the order of the first filter, the second filter, and the third filter from upstream to downstream. In each example, circulation filtration was performed in which the resin composition (P)-2 for forming a phase-separated structure was passed through each filter 10 times.

The types of filters (1), (2) and (3) are shown in Table 1.

TABLE 4

| | | | | Filtering conditions | |
|---|---|---|---|---|---|
| | Filter | | | Filtering | Filtering |
| | 1st | 2nd | 3rd | pressure | temperature |
| | filter | Filter | filter | (MPa) | (° C.) |
| Example 6 | (1) | — | — | 0.2 | 23 |
| Example 7 | (1) | (2) | — | 0.2 | 23 |
| Example 8 | (1) | (3) | — | 0.2 | 23 |
| Example 9 | (3) | (1) | — | 0.2 | 23 |
| Example 10 | (1) | (2) | (3) | 0.2 | 23 |
| Comparative | (2) | — | — | 0.2 | 23 |
| Example 4 | | | | | |
| Comparative | (3) | — | — | 0.2 | 23 |
| Example 5 | | | | | |
| Comparative | (2) | (3) | — | 0.2 | 23 |
| Example 6 | | | | | |

«Evaluation of Purified Product of Resin Composition for Forming a Phase-Separated Structure (2)»

Regarding the purified product of the resin composition for forming a phase-separated structure of each example, a light scattering type liquid particle counter [manufactured by Rion Co., Ltd., model number: KS-41B, light source: diode pumped solid state laser (wavelength 532 nm, rated output 500 mW), rated flow rate: 5 mL/min] based on a dynamic light scattering method, was used to count the number of objects having a size of 0.11 μm or more. The counting was performed 3 times, and the average value was used as the measured value. The light scattering type liquid particle counter was used after calibrating with a PSL (Polystyrene Latex) standard particle solution. The results are indicated under “Number of particles (number/cm³)” in Table 5.

TABLE 5

| | Number of particles |
|---|---|
| | (Number/cm³) |
| Example 6 | 2.5 |
| Example 7 | 0.4 |
| Example 8 | 1.6 |
| Example 9 | 1.6 |
| Example 10 | 0.2 |
| Comparative | 25.8 |
| Example 4 | |
| Comparative | 34.1 |
| Example 5 | |
| Comparative | 22.9 |
| Example 6 | |

As seen from the results shown in Table 5, it was confirmed that the number of particles were reduced in the purified product of the resin composition for forming a phase-separated structure of Examples 6 to 10, as compared to the purified product of the resin composition for forming a phase-separated structure of Comparative Examples 4 to 6.

### BRIEF DESCRIPTION OF THE DRAWINGS

1a: Spherical cell, 1b: Spherical cell, 5: Communicating pore

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A method of producing a purified product of a resin composition for forming a phase-separated structure, the method comprising:
subjecting a resin composition for forming a phase-separated structure to filtration using a filter having a porous structure in which adjacent spherical cells are mutually communicating,
wherein the filter is provided with a porous membrane containing at least one resin selected from the group consisting of polyimide and polyamideimide, and
the resin composition for forming a phase-separated structure comprises a block copolymer and an organic solvent component.

2. The method according to claim 1, wherein the average diameter of the spherical cells is 10 to 500 nm.

3. The method according to claim 1, wherein the porous structure comprises communicating pores having an average pore diameter of 0.01 to 50 nm as determined by BET method.

4. The method according to claim 1, wherein the filter is provided with a polyimide porous membrane.

5. The method according to claim 1, further comprising:
after subjecting a resin composition for forming a phase-separated structure to filtration, further subjecting the resin composition for forming a phase-separated structure to filtration using a filter provided with a porous membrane comprising a polyamide resin.

6. The method according to claim 1, wherein the resin composition for forming a phase-separated structure further comprises an ion liquid containing a compound having a cation moiety and an anion moiety.

7. A method of producing a structure containing phase-separated structure, the method comprising:
obtaining a purified product of a resin composition for forming a phase-separated structure by the method according to claim 1;
forming a BCP layer containing the block copolymer on a substrate using the purified product of the resin composition; and
phase-separating the BCP layer to obtain a structure containing a phase-separated structure.

8. A purified product of a resin composition for forming a phase-separated structure wherein the number of objects having a size of 0.11pm or more is less than 5/cm³, as counted by a light scattering type liquid-borne particle counter.

9. A method of producing a structure containing a phase-separated structure, the method comprising:
forming a BCP layer containing the block copolymer on a substrate using the purified product of a resin composition for forming a phase-separated structure according to claim 8; and
phase-separating the BCP layer to obtain a structure containing a phase-separated structure.
